(19) United States
(12) Patent Application Publication
(10) Pub. No.: US 2024/0417263 A1
(43) Pub. Date: Dec. 19, 2024

(54) METHOD OF FORMING GRAPHENE FILMS

(71) Applicant: University of Massachusetts, Boston, MA (US)

(72) Inventors: James J. Watkins, South Hadley, MA (US); Uzodinma Okoroanyanwu, Florence, MA (US); Ayush Bhardwaj, Amherst, MA (US)

(21) Appl. No.: 18/702,777

(22) PCT Filed: Oct. 18, 2022
(86) PCT No.: PCT/US2022/078299

§ 371 Date: Apr. 18, 2024

Related U.S. Application Data
(60) Provisional application No. 63/262,656, filed on Oct. 18, 2021.

(51) Int. Cl. C01B 32/184; H01G 11/32; H05K 9/00

(52) U.S. Cl. CPC C01B 32/184; H01G 11/32; H05K 9/0088; C01P 2006/40

(57) ABSTRACT

Methods for formation of graphene films, graphene films made thereby, and applications thereof. A method for the formation of a graphene film includes coating a polymeric graphene precursor on a substrate. The method includes irradiating the polymeric graphene precursor coated on the substrate with a pulsed high intensity light source emitting at more than a single wavelength and with a pulse duration of less than one second, to convert the polymeric graphene precursor to the graphene film.

### CROSS-REFERENCE TO RELATED APPLICATION

This application claims the benefit of priority to U.S. Provisional Patent Application Ser. No. 63/262,656 entitled filed Oct. 18, 2021, the disclosure of which is incorporated herein in its entirety by reference.

### STATEMENT OF GOVERNMENT SUPPORT

This invention was made with Government support under W911NF-19-2-0152 awarded by the U.S. Army Research Laboratory. The U.S. Government has certain rights in this invention.

### BACKGROUND

Graphene is a nanomaterial with two-dimensional honeycomb lattice of sp² hybridized carbon atoms. It has many unique properties such as high electrical conductivity, high thermal conductivity, good mechanical properties, high surface area, excellent chemical properties, good biocompatibility, and the like. All these properties make graphene an ideal candidate for potential applications in nanoelectronics, energy storage, biosensing, catalysis, nanocomposites, pharmaceuticals, to mention but a few. There are three main forms of graphene materials in use today: graphene oxide, reduced graphene oxide and pristine single and multilayer graphene. Of all the forms of graphene, pristine graphene possesses the best of the above-named properties.

Many graphene preparatory methods have been reported in the literature. These methods can be broadly categorized into top-down or bottom-up approaches. In top-down approaches, graphene is prepared via mechanical exfoliation, chemical exfoliation of graphite and graphite oxide, laser exfoliation of graphite, chemical reduction of graphene oxide, electrochemical reduction of graphene oxide, photothermal reduction of GO and photolysis of various precursors using flash lamp. In bottom-up approaches, graphene is produced via solution-based chemical synthesis, via solvothermal synthesis, via chemical vapor deposition on different substrates such as metals catalysts such as copper, ruthenium, nickel, via epitaxial growth on SiC, via laser-induced epitaxial growth, as well as via arc discharge.

Most of the above-mentioned methods, except electrochemical reduction and CVD approaches, are not scalable to large scale production. Most of them are extremely energy intensive, are operated under harsh conditions, are expensive and are very slow to execute.

### SUMMARY OF THE INVENTION

The present invention provides a method for the formation of a graphene film. The method includes coating a polymeric graphene precursor on a substrate. The method includes irradiating the polymeric graphene precursor coated on the substrate with a pulsed high intensity light source emitting at more than a single wavelength and with a pulse duration of less than one second, to convert the polymeric graphene precursor to the graphene film.

The present invention provides a method for the formation of a graphene film. The method includes coating a polymeric graphene precursor on a substrate that includes a carbon fiber, carbon mesh, carbon fabric, carbon composite, graphene composite, graphene, a carbon film, or a combination thereof, wherein the polymeric graphene precursor and the substrate have different chemical compositions. The method includes irradiating the polymeric precursor coated on the substrate with a pulsed high intensity light source emitting at more than a single wavelength and with a pulse duration of less than one second, to convert the polymeric graphene precursor to the graphene film.

The present invention provides a graphene film formed by the method of the present invention. The graphene film can be a patterned or unpatterned graphene film.

The present invention provides an electrochemical energy storage device, an electromagnetic shielding material, a chemical or biological sensor, a post-CMOS nanoelectronic device, a heat shielding material, a structural composite, a filter, or a combination thereof, including a graphene film formed by the method of the present invention.

Various aspects of the method of the present invention can have advantages over other methods of forming graphene films. For example, in various aspects, the method of the present invention can be performed at lower temperatures than other methods, enabling formation of graphene films on thermally-sensitive materials. In various aspects, the rapid pyrolysis of the polymer graphene precursor can lower, minimize, or avoid oxidation of the resulting graphene film. In various aspects, the method can form graphene films having similar or better thermal, electrical, and/or mechanical stability, as compared to graphene films formed by other methods. In various aspects, the method of the present invention overcomes the limitations and drawbacks of conventional methods of making graphene, in terms of energy budget, throughput, scalability, and/or versatility with respect to the precursors.

In various aspects, the method of the present invention can form graphene without a catalyst or a catalytic substrate. In various aspects, the method of the present invention can be performed at ambient room conditions in terms of temperature, pressure, and humidity. In various aspects, the method of the present invention offers a much higher throughput relative to other methods of making graphene because the entire pyrolysis process can take place in a timeframe of microseconds and can be completed a time frame of milliseconds, depending on the number of pulses applied. In various aspects, the method of the present invention is a safer and more environmentally friendly alternative to conventional methods of making graphene, as it does not require hazardous or polluting chemicals, or extremely high electrical power or mechanical force, or extreme pressure. In various aspects, the method of the present invention is a simpler alternative to conventional methods of making graphene, as it is a can synthesize graphene in a single irradiation step. In various aspects, the method of the present invention is a less energy intensive alternative conventional methods of making graphene, as it uses less energy to operate the flash lamp and its control electronics than the energy consumption of other methods. In various aspects, the method of the present invention is a cheaper alternative to conventional methods of making graphene, as it can be performed using simple equipment equipped with a flash lamp or other appropriate radiation sources such as high intensity light emitting diodes that can be operated in ambient conditions that do not require vacuum or extreme environments for their operation. In various aspects, the method of the present invention is a more scalable alternative to conventional methods of making graphene, as it can be operated in a roll-to-roll format, enabling extremely high throughput, and large area graphene materials, in relatively short time on the order of minutes, depending on the length of the substrate. In various aspects, the method of the present invention can make graphene on a wide range of substrates, including metals (stainless-steel, copper, nickel, aluminum, gold, and the like), semiconductors (silicon, silicon carbide, gallium arsenide, and indium gallium arsenide, aluminum gallium arsenide wafers, and the like), plastics (polyimides, polyaramids, polyesters, and the like), or a combination thereof.

### BRIEF DESCRIPTION OF THE FIGURES

The drawings illustrate generally, by way of example, but not by way of limitation, various aspects of the present invention.

FIG. 1 illustrates a scheme for preparation of graphene via photothermal pyrolysis of thin precursor films at ambient conditions, in accordance with various aspects.

FIGS. 2A-2C illustrates examples of various precursor materials, in accordance with various aspects.

FIG. 2D illustrates a method of synthesizing polybenzoxazine, in accordance with various aspects.

FIG. 3 illustrates a processing scheme for the photothermal pyrolysis of an unpatterned precursor film and its conversion to a graphene composite, in accordance with various aspects.

FIG. 4 illustrates a method of curing a benzoxazine monomer and converting it to polybenzoxazine, in accordance with various aspects.

FIG. 5 illustrates a processing scheme for the cyclization of polyacrylonitrile and photothermal pyrolysis of an unpatterned cyclized polyacrylopnitile precursor film and its conversion to a graphene composite, in accordance with various aspects.

FIG. 6 illustrates a processing scheme for the photothermal pyrolysis of pristine carbon fiber and its conversion to a graphene composite, in accordance with various aspects.

FIG. 7 illustrates a process sequence for the photothermal pyrolysis process for obtaining patterned pristine graphene, in accordance with various aspects.

FIG. 8 illustrates a process sequence for the photothermal pyrolysis process for obtaining a screen-printed graphene composite, in accordance with various aspects.

FIG. 9A illustrates Emission spectra of a Pulse Forge tool as a function of pulse voltage, in accordance with various aspects.

FIG. 9B illustrates absorption spectra of glass substrate, benzoxazine monomer, and cured poly(benzoxazine) film, in accordance with various aspects.

FIG. 9C illustrates a temperature-time profile obtained from cured poly(benzoxazine) film photothermally pyrolyzed with a low power process, in accordance with various aspects.

FIG. 9D illustrates a temperature-time profile obtained from cured poly(benzoxazine) film photothermally pyrolyzed with high-power process, in accordance with various aspects.

FIG. 9E illustrates FTIR spectra of a benzoxazine monomer, poly(benzoxazine), and a photothermally produced graphene composite, in accordance with various aspects.

FIG. 9F illustrates TGA profiles of poly(benzoxazine), graphene composite, and carbon fiber, in accordance with various aspects.

FIG. 10A illustrates an optical image of a cured precursor film, in accordance with various aspects.

FIG. 10B illustrates an optical image of a graphene/carbon fiber composite, in accordance with various aspects.

FIG. 10C illustrates a SEM image of a graphene/carbon fiber composite, in accordance with various aspects.

FIG. 10D illustrates a SEM image of a graphene/carbon fiber composite, in accordance with various aspects.

FIG. 11A illustrates an optical image of a 1K, plain weave, 228.6 mm thick pristine fine mesh carbon fiber, in accordance with various aspects.

FIG. 11B illustrates an optical image of a carbon fiber/graphene composite obtained after one layer of coating and pyrolysis of polybenzoxazine precursor film on 1K, plain weave, 228.6 mm thick pristine fine mesh carbon fiber, in accordance with various aspects.

FIG. 11C illustrates an optical image of a carbon fiber/graphene composite obtained after two layers of coating and pyrolysis of polybenzoxazine precursor film on 1K, plain weave, 228.6 mm thick pristine fine mesh carbon fiber, in accordance with various aspects.

FIG. 11D illustrates a SEM image of the composite shown in FIG. 11C, in accordance with various aspects.

FIG. 12A illustrates Raman spectra of a carbon fiber and a graphene/carbon fiber composite, in accordance with various aspects.

FIG. 12B illustrates an X-ray diffraction pattern of a graphene/carbon fiber composite, in accordance with various aspects.

FIG. 12C illustrates XPS spectra of a graphene/carbon fiber composite, in accordance with various aspects.

FIG. 13A illustrates an image of a graphene/carbon composite derived via a low power pulse modulation process, in accordance with various aspects.

FIG. 13B illustrates an image of a graphene/carbon composite derived via a high power pulse modulation process, in accordance with various aspects.

FIG. 13C illustrates an image of a graphene/carbon composite derived via a high power pulse modulation process, in accordance with various aspects.

FIG. 13D illustrates Raman spectra of graphene/carbon composites derived via low and high-power pulse power modulation processes, in accordance with various aspects.

FIG. 14A illustrates a transmission electron micrograph of a graphene/carbon fiber composite, in accordance with various aspects.

FIG. 14B illustrates a transmission electron micrograph of a graphene/carbon fiber composite, in accordance with various aspects.

FIG. 14C illustrates a transmission electron micrograph of amorphous carbon, in accordance with various aspects.

FIG. 15A illustrates a SEM image of thermally cured imprinted features, in accordance with various aspects.

FIG. 15B illustrates a SEM image of graphene features derived via photothermal pyrolysis of features shown in FIG. 15A, in accordance with various aspects.

FIG. 15C illustrates a SEM image that is a magnified via of features shown in FIG. 15B, in accordance with various aspects.

FIG. 15D illustrates a SEM image that is a magnified via of features shown in FIG. 15B, in accordance with various aspects.

FIG. 16 illustrates Raman spectra of imprinted and thermally cured structures, and graphene features derived from them upon photothermal pyrolysis in air, in accordance with various aspects.

FIG. 17 illustrates an optical image of graphene/carbon fiber composite derived from the layer-by-layer coating, followed by photothermal pyrolysis of cyclized polyacrylonitrile after two rounds of coating and pyrolysis, in accordance with various aspects.

FIGS. 18A-18F illustrate SEM images of a graphene/carbon fiber composite derived from the layer-by-layer coating, followed by photothermal pyrolysis of cyclized polyacrylonitrile after two rounds of coating and pyrolysis, in accordance with various aspects.

FIG. 19 illustrates FTIR spectra of polyacrylonitrile (before cyclization) and cyclized polyacrylonitrile film, in accordance with various aspects.

FIG. 20A illustrates a Raman spectrum of a graphene/carbon fiber composite derived from the layer-by-layer coating, followed by photothermal pyrolysis of cured poly(furan diepoxy) after two and three rounds of coating and pyrolysis, wherein the precursor film was coated on a carbon fiber substrate, in accordance with various aspects.

FIG. 20B illustrates a Raman spectrum of a graphene/carbon fiber composite derived from the layer-by-layer coating, followed by photothermal pyrolysis of cured poly(furan diepoxy) after two and three rounds of coating and pyrolysis, wherein the precursor film was coated on a stainless steel substrate, in accordance with various aspects.

FIG. 21A illustrates an optical image of dimensionally stable polyimide/graphene composite electrode structures derived from the photothermal pyrolysis in air of screen-printed and thermally cured cyclized polyacrylonitrile electrode structures, in accordance with various aspects.

FIG. 21B illustrates a Raman spectrum of dimensionally stable polyimide/graphene composite electrode structures derived from the photothermal pyrolysis in air of screen-printed and thermally cured cyclized polyacrylonitrile electrode structures, in accordance with various aspects.

FIG. 22A illustrates an optical image of pristine unpyrolyzed carbon fiber fabric, in accordance with various aspects.

FIG. 22B illustrates an optical image of photothermally pyrolyzed carbon fiber fabric, in accordance with various aspects.

FIG. 23A illustrates an FTIR spectrum of pristine carbon fiber fabric, in accordance with various aspects.

FIG. 23B illustrates Raman spectra of pristine carbon fiber fabric and photothermally pyrolyzed pristine carbon fiber fabric as a function of xenon flash lamp pulse power, in accordance with various aspects.

FIG. 24A illustrates a low magnification SEM image of a MnO₂-deposited PPG, in accordance with various aspects.

FIG. 24B illustrates a low magnification SEM image of a MnO₂-deposited PPG, in accordance with various aspects.

FIG. 24C illustrates a high magnification SEM image of a MnO₂-deposited PPG, in accordance with various aspects.

FIG. 24D illustrates a comparison of Raman spectra of MnO₂-deposited PPG and PPG, in accordance with various aspects.

FIG. 24E illustrates XRD profiles of PPG and corresponding MnO₂ deposited on PPG, in accordance with various aspects.

FIG. 24F illustrates an XPS analysis of MnO₂ deposited on PPG, in accordance with various aspects.

FIG. 25A illustrates CV curves at 50 mV/s of PPG prepared at different power pulse and CF, in accordance with various aspects.

FIG. 25B illustrates CV curves of PPG from PBz at different scan rate, in accordance with various aspects.

FIG. 25C illustrates GCD profiles at different current density of fabricated device, in accordance with various aspects.

FIG. 25D illustrates a Nyquist plot of PPG in the frequency of 10⁴ to 0.1 Hz, in accordance with various aspects.

FIG. 26A illustrates CV curves at various scan rate of a symmetric device prepared using MnO₂ deposited on PPG, in accordance with various aspects.

FIG. 26B illustrates GCD profiles at different current density of a symmetric device prepared using MnO₂ deposited on PPG, in accordance with various aspects.

FIG. 26C illustrates capacitance (F/g) as a function of current density for a symmetric device prepared using MnO₂ deposited on PPG, in accordance with various aspects.

FIG. 27A illustrates a Ragone plot of a symmetric device prepared using MnO₂ deposited on PPG, in accordance with various aspects.

FIG. 27B illustrates a device demonstration by lighting LED using three devices connected in series, in accordance with various aspects.

FIG. 28A illustrates a photograph of an experimental setup for EMI shielding measurement, including a programmable network analyzer, waveguide, and sample holder assembly (top left), a photograph showing a close-up of the sample holder assembly, in accordance with various aspects (bottom left), a photograph showing a close of the sample holder (middle) and a photograph showing the sample within the sample holder (right), in accordance with various aspects.

FIG. 28B illustrates a schematic showing a front view of the sample placed within the sample holder (left), and a schematic showing a side view of sample placement within the sample holder (right), in accordance with various aspects.

FIG. 29 illustrates SE versus frequency, showing multi-band (C-, X- and Ku bands) EMI shielding effectiveness of graphene/carbon fiber composites in 2-layer configuration, in accordance with various aspects.

FIG. 30 illustrates an UV absorption spectrum of Kapton, in accordance with various aspects.

FIG. 31A illustrates an optical image of PANI on CF (left) and PANI-derived graphene on CF (right), in accordance with various aspects.

FIG. 31B illustrates TGA profiles of PANI, PANI-derived graphene, and pure CF, in accordance with various aspects.

FIG. 31C illustrates Raman spectra of pure CF (top), PANI-derived graphene on CF (middle), and PANI produced via conventional carbonization at 1000° C. (bottom), in accordance with various aspects.

FIG. 32A illustrates a SEM image of electrochemically deposited PANI, in accordance with various aspects.

FIG. 32B illustrates a SEM image of photothermally produced graphene from PANI, in accordance with various aspects.

FIG. 32C illustrates a C1s spectrum of photothermally produced graphene from PANI, in accordance with various aspects.

FIG. 33A illustrates a CV curve of PANI-derived graphene and CF in 0.5 M sodium sulfate at 50 mV/s, in accordance with various aspects.

FIG. 33B illustrates CV curves of PANI-derived graphene in 1M sulfuric acid at various scan rates (10 mV/s to 100 mV/s), in accordance with various aspects.

FIG. 33C illustrates GCD curves of PANI derived graphene at various current densities, in accordance with various aspects.

FIG. 34 illustrates a schematic diagram of an eye wear side arm with energy storage capability formed from polyaniline on carbon fiber, in accordance with various aspects.

FIG. 35A illustrates a screen-printed LED circuit including a cPAN precursor, in accordance with various aspects.

FIG. 35B illustrates an LED graphene circuit derived from photothermal pyrolysis of the screen printed cPAN precursor, in accordance with various aspects.

FIG. 35C illustrates a demonstration of successful integration of white light LED into the graphene circuit of FIG. 35B, driven by an external power supply, with the graphene trace having a sheet resistance of 100-200 ohm/sq, in accordance with various aspects.

### DETAILED DESCRIPTION OF THE INVENTION

Reference will now be made in detail to certain aspects of the disclosed subject matter, examples of which are illustrated in part in the accompanying drawings. While the disclosed subject matter will be described in conjunction with the enumerated claims, it will be understood that the exemplified subject matter is not intended to limit the claims to the disclosed subject matter.

Throughout this document, values expressed in a range format should be interpreted in a flexible manner to include not only the numerical values explicitly recited as the limits of the range, but also to include all the individual numerical values or sub-ranges encompassed within that range as if each numerical value and sub-range is explicitly recited. For example, a range of “about 0.1% to about 5%” or “about 0.1% to 5%” should be interpreted to include not just about 0.1% to about 5%, but also the individual values (e.g., 1%, 2%, 3%, and 4%) and the sub-ranges (e.g., 0.1% to 0.5%, 1.1% to 2.2%, 3.3% to 4.4%) within the indicated range. The statement “about X to Y” has the same meaning as “about X to about Y,” unless indicated otherwise. Likewise, the statement “about X, Y, or about Z” has the same meaning as “about X, about Y, or about Z,” unless indicated otherwise.

In this document, the terms “a,” “an,” or “the” are used to include one or more than one unless the context clearly dictates otherwise. The term “or” is used to refer to a nonexclusive “or” unless otherwise indicated. The statement “at least one of A and B” or “at least one of A or B” has the same meaning as “A, B, or A and B.” In addition, it is to be understood that the phraseology or terminology employed herein, and not otherwise defined, is for the purpose of description only and not of limitation. Any use of section headings is intended to aid reading of the document and is not to be interpreted as limiting; information that is relevant to a section heading may occur within or outside of that particular section.

In the methods described herein, the acts can be carried out in any order without departing from the principles of the invention, except when a temporal or operational sequence is explicitly recited. Furthermore, specified acts can be carried out concurrently unless explicit claim language recites that they be carried out separately. For example, a claimed act of doing X and a claimed act of doing Y can be conducted simultaneously within a single operation, and the resulting process will fall within the literal scope of the claimed process.

The term “about” as used herein can allow for a degree of variability in a value or range, for example, within 10%, within 5%, or within 1% of a stated value or of a stated limit of a range, and includes the exact stated value or range.

The term “substantially” as used herein refers to a majority of, or mostly, as in at least about 50%, 60%, 70%, 80%, 90%, 95%, 96%, 97%, 98%, 99%, 99.5%, 99.9%, 99.99%, or at least about 99.999% or more, or 100%. The term “substantially free of” as used herein can mean having none or having a trivial amount of, such that the amount of material present does not affect the material properties of the composition including the material, such that about 0 wt % to about 5 wt % of the composition is the material, or about 0 wt % to about 1 wt %, or about 5 wt % or less, or less than, equal to, or greater than about 4.5 wt %, 4, 3.5, 3, 2.5, 2, 1.5, 1, 0.9, 0.8, 0.7, 0.6, 0.5, 0.4, 0.3, 0.2, 0.1, 0.01, or about 0.001 wt % or less, or about 0 wt %.

As used herein, the term “polymer” refers to a molecule having at least one repeating unit and can include copolymers.

### Method of Forming a Graphene Film.

Various aspects of the preset invention provide a method for the forming of a graphene film. The method includes coating a polymeric graphene precursor on a substrate. The method also includes irradiating the polymeric graphene precursor coated on the substrate with a pulsed high intensity light source that emits at more than a single wavelength and having a pulse duration of less than one second. The irradiating converts the polymeric graphene precursor to the graphene film. The irradiating can pyrolyze the polymeric graphene precursor to form the graphene film.

The formed graphene film can be a composite graphene film or a graphene non-composite film. The formed graphene film can include the substrate, such that the formed graphene film is coated on the substrate. The substrate can be any suitable material, such as a thermally sensitive material or a material that is not thermally sensitive. The substrate and the polymeric graphene precursor can have the same chemical compositions. The substrate and the polymeric graphene precursor can have different chemical compositions. The substrate and the formed graphene film on the substrate can have different chemical compositions. The substrate can be a material other than a graphene film or a polymeric graphene film precursor.

The irradiating includes irradiating the polymeric graphene precursor that is coated on the substrate. The irradiating can include irradiating the polymeric graphene precursor or both the polymeric graphene precursor and the substrate. The irradiating of the substrate can cause no change in the substrate, or can cause a change in the substrate. In various aspects, the irradiating of the substrate can convert the substrate to a material including graphene. In various aspects, the irradiating of the substrate does not convert the substrate to a material including graphene. The irradiating of the polymeric graphene precursor can be performed in air, inert gas, or any suitable gas. The irradiating of the polymeric graphene precursor can be performed in air.

The irradiating can include irradiating and/or maintaining the polymeric graphene precursor at a temperature that is less than 100° C., such as 0° C. to 99° C., or 10° C. to 50° C., or 20° C. to 30° C., or less than 100° C. and greater than or equal to 0° C., 1, 2, 4, 6, 8, 10, 12, 14, 16, 18, 20, 22, 24, 26, 28, 30, 32, 34, 36, 38, 40, 45, 50, 55, 60, 65, 70, 75, 80, 85, 90, or 95° C. The irradiating can include irradiating the polymeric graphene precursor at room temperature or ambient temperature. The irradiating can include substantially maintaining a pre-irradiation temperature of the polymeric graphene precursor throughout the irradiating. The irradiating can include increasing a temperature of the polymeric graphene precursor by less than or equal to 10° C., less than or equal to 2° C., or by 0° C., or by less than or equal to 100° C. and greater than or equal to 0.001° C., 0.005, 0.01, 0.05, 0.1, 0.5, 1, 1.5, 2, 2.5, 3, 3.5, 4, 4.5, 5, 6, 7, 8, 9, 10, 12, 14, 16, 18, 20, 25, 30, 35, 40, 45, 50, 55, 60, 65, 70, 75, 80, 85, 90, or 95° C., relative to a pre-irradiation temperature of the precursor film. The method can include localizing light absorption to the precursor film such that any temperature increase of the polymeric graphene precursor is less than a desired limit. By localizing light absorption to the precursor film during photothermal treatment, the process can be carried out at ambient temperature, enabling the preparation of high-quality graphene and graphene composites on any substrate, including thermally sensitive substrates, and without the need for a catalyst. Various aspects of the method of the present invention can leave the substrate free of damage relative to a state of the substrate prior to the coating and irradiating. The method can enable formation of the graphene film without damaging the substrate and by which the polymeric graphene precursor and the substrate can be independently selected, providing advantages in tuning the graphene material on any arbitrary substrate.

The light source can be any suitable light source that induces graphene formation from the polymeric graphene precursors described herein. The light source can be any suitable light source that has an emission band that overlaps with an absorption band of the polymeric graphene precursor. The light source can include a xenon flash lamp, a halogen flashlamp, a light emitting diode, more than one light emitting diodes, or a combination thereof. The light source can include or be a xenon flash lamp. The light source can include emission wavelengths that overlap the absorption wavelengths of the polymeric graphene precursor. The light source can include mission wavelengths that are in the range of 100 nm to 2000 nm, 300 nm to 800 nm, 400 nm to 600 nm, or equal to or less than 2000 nm and greater than or equal to 100 nm, 150, 200, 250, 300, 350, 400, 410, 420, 430, 440, 450, 460, 470, 480, 490, 500, 510, 520, 530, 540, 550, 560, 570, 580, 590, 600, 650, 700, 750, 800, 850, 900, 950, 1000, 1200, 1400, 1600, or 1800 nm.

The pulse duration of the light source during the irradiating can be shorter than a thermal equilibrium time of the polymeric graphene precursor, such that the temperature increase of the polymeric graphene precursor during the irradiating thereof is small, minimal, or none. The pulse duration can be any suitable pulse duration, such as 1 to 999 milliseconds, 200 to 900 milliseconds, 400 to 800 milliseconds, or less than or equal to 999 milliseconds and greater than or equal to 1 millisecond, 2 milliseconds, 5, 10, 50, 100, 150, 200, 250, 300, 350, 400, 450, 500, 550, 600, 650, 700, 750, 800, 850, 900, or 950 milliseconds.

The light source can have any suitable intensity during the irradiating, such as an intensity of 100 V to 2000 V, 400 V to 700 V, or less than or equal to 2000 V and greater than or equal to 100 V, 150, 200, 250, 300, 350, 400, 450, 500, 550, 600, 650, 700, 800, 900, 1000, 1100, 1200, 1300, 1400, 1500, 1600, 1700, 1800, or 1900 V. During the irradiating, the light source can have an energy density per pulse of 0.1 J/cm₂ to 100 J/cm₂, 1 J/cm₂ to 10 J/cm², 2 J/cm² to 9 J/cm², or less than or equal to 100 J/cm² and greater than or equal to 0.1 J/cm², 0.5, 1, 2, 3, 4, 5, 6, 7, 8, 9, 10, 12, 14, 16, 18, 20, 25, 30, 35, 40, 45, 50, 55, 60, 65, 70, 75, 80, 85, 90, or 95 J/cm². During the irradiating, the light source can have a total areal density of 10 J/cm² to 1000 J/cm², 30 J/cm² to 200 J/cm², or less than or equal to 1000 J/cm² and greater than or equal to 10 J/cm², 20, 30, 40, 50, 60, 70, 80, 90, 100, 110, 120, 130, 140, 150, 160, 170, 180, 190, 200, 250, 300, 400, 500, 600, 700, 800, or 900 J/cm².

The light source can have any suitable pulse frequency, such as 0.001 Hz to 1000 Hz, 0.1 Hz to 10 Hz, 0.5 Hz to 1 Hz, or less than or equal to 1000 Hz and greater than or equal to 0.1 Hz, 0.2, 0.3, 0.4, 0.5, 0.6, 0.7, 0.8, 0.9, 1, 1.1, 1.2, 1.3, 1.4, 1.5, 1.6, 1.8, 2, 2.5, 3, 4, 5, 6, 8, 10, 15, 20, 25, 30, 35, 40, 45, 50, 60, 80, 100, 150, 200, 250, 300, 400, 600, 800, or 900 Hz. The irradiating can include any suitable number of pulses of the light source, such as 5 to 1000 pulses of the light source, 10 to 40 pulses of the light source, or less than or equal to 1000 pulses and greater than or equal to 5 pulses, 10, 12, 14, 16, 18, 20, 22, 24, 26, 28, 30, 32, 34, 36, 38, 40, 45, 50, 55, 60, 65, 70, 75, 80, 85, 90, 95, 100, 110, 120, 140, 160, 180, 200, 250, 300, 400, 500, 600, 700, 800, or 900 pulses.

The coating of the polymeric graphene precursor on the substrate can be performed by any suitable means. For example, coating the polymeric graphene precursor on the substrate can include printing, offset printing, ink jet printing, transfer printing, aerosol jet printing, microcontact printing, embossing, nanoimprint lithography, optical lithography lithography, electron beam lithography, ion beam lithography, or a combination thereof. The method can include curing the coating of the polymeric graphene precursor to form a cured film of the polymeric graphene precursor, such as thermal curing, light or UV curing, or a combination thereof. The irradiating can include irradiating the cured film. In other aspects, the method is free of curing and the irradiating can include irradiating the uncured coating of the polymeric graphene precursor.

The polymeric graphene precursor on the substrate can include a patterned polymeric graphene precursor; e.g., the polymeric graphene precursor can be patterned. The patterning can be introduced to the coating after the coating is applied to the substrate, or the coating can be introduced to the coating at the same time as it is being applied. The patterned coating of the polymeric graphene precursor can be formed by any suitable method, such as printing, offset printing, ink jet printing, transfer printing, aerosol jet printing, microcontact printing, or a combination thereof. The patterned coating of the polymeric graphene precursor can be formed by embossing, nanoimprint lithography, or a combination thereof. The patterned coating of the polymeric graphene precursor can be formed by optical lithography lithography, or electron beam lithography, or ion beam lithography.

The polymeric graphene precursor can be any suitable polymeric precursor that forms a graphene film under the irradiation conditions described herein. For example, the polymeric graphene precursor can include a polymer that includes a disubstituted benzene, a benzene substituted with one or more chromophores, polycyclic aromatic rings, or a combination thereof. The polymeric graphene precursor can include a polymer that includes nitroaniline, aniline, nitrophenol, biphenyl (e.g., two conjugated benzene rings), nitrobenzene, benzaldehyde, acetophenone, pyrene, pentacene, anthracene, tetracene, or a combination thereof. The polymeric graphene precursor can include a polymer chosen from resol, an oligomer of pyrene pitch, cyclized polyacrylonitrile, polyaniline, carbon fiber, a thermosetting resin network formed from blending and crosslinking polybenzoxazines with an epoxy, and combinations thereof. The polymeric graphene precursor can include a polymer chosen from poly(3-phenyl-2,4-dihydro-1,3-benzoxazine), poly(phenyl benzoxazine), poly(3-furanyl-2,4-dihydro-1,3-benzoxazine), poly(furanyl benzoxazine), poly(phenol-co-formaldehyde), resol, oligomers of pyrene pitch, cyclized polyacrylonitrile, pristine carbon fiber, polyaniline, a thermosetting resin network formed from blending and crosslinking polybenzoxazines with bis-phenol-A furfuryl diglycidyl ether, and combinations thereof. In various aspects, the polymeric graphene precursor includes polyaniline. In various aspects, the polymeric graphene precursor includes polyaniline, and the polymeric graphene precursor is irradiated to form the graphene firm with reduced or zero requirement of higher temperature crosslinking or curing; for example, such irradiation can be performed at (e.g., maintained at) room temperature, or at equal to or less than 30° C., 35, 40, 45, or 50° C. In various aspects, the polymeric graphene precursor includes polyaniline, and the produced graphene film is a porous graphene film.

The polymeric graphene precursor can have an absorption band that overlaps with an emission band of the pulsed light source. The polymeric graphene precursor can have an absorption band that is in the range of 100 nm to 2000 nm, 300 nm to 800 nm, 400 nm to 600 nm, or equal to or less than 2000 nm and greater than or equal to 100 nm, 150, 200, 250, 300, 350, 400, 410, 420, 430, 440, 450, 460, 470, 480, 490, 500, 510, 520, 530, 540, 550, 560, 570, 580, 590, 600, 650, 700, 750, 800, 850, 900, 950, 1000, 1200, 1400, 1600, or 1800 nm.

The substrate can be any suitable substrate. The substrate can include plastic, metal, fabric, textile fabric, carbon, or a combination thereof. A substrate including carbon can include a carbon fiber, a carbon mesh, a carbon fabric, a carbon composite, a graphene composite, graphene, a carbon film, or a combination thereof. In various aspects, a substrate including carbon can form graphite, graphene, or a combination thereof, during the irradiation. In other aspects, a substrate including carbon can remain unchanged during the irradiation, or can transform to materials other than graphite and/or graphene.

The graphene film can have a conductivity of at least 150 S/cm, such as 150-5000 S/cm, 150 S/cm-1000 S/cm, 150-500 S/cm, or less than or equal to 5000 S/cm and greater than or equal to 150 S/cm, 160, 170, 180, 190, 200, 220, 240, 260, 280, 300, 320, 340, 360, 380, 400, 420, 440, 460, 480, 500, 550, 600, 650, 700, 750, 800, 900, 1,000, 1,250, 1,500, 1,750, 2,000, 2,500, 3,000, or 3,500 S/cm.

The graphene film can have a ratio of less than 1.0 between a characteristic disorder band (D-band) with a peak near 1350 cm⁻¹ and a characteristic graphitic band (G band) with a peak near 1582 cm⁻¹, as determined by Raman spectroscopy. The graphene film can have a ratio of less than 1 between a characteristic 2Dband with a peak near 2700 cm⁻¹ and a characteristic graphitic band (G band) with a peak near 1582 cm⁻¹ that is fittable with a single Lorentzian function, as determined by Raman spectroscopy.

The irradiating can include pulse power modulation. The method can include tuning a microstructure of the graphene film using the pulse power modulation

### Graphene Film.

Various aspects of the present invention provide a graphene film that is formed by the method of the present invention. The graphene film can be a graphene film coated on the substrate described herein. The graphene film can be a patterned graphene film, or an unpatterned graphene film.

### Devices Including the Graphene Film.

Various aspects of the present invention provide an electrochemical energy storage device, an electromagnetic shielding material, a chemical or biological sensor, a post-CMOS nanoelectronic device, a heat shielding material, a structural composite, a filter, or a combination thereof, including a graphene film formed the method of the present invention. For example, the graphene film formed by the method can find applications in electrochemical energy storage devices as electrodes in supercapacitors, and batteries, in electromagnetic interference and electromagnetic pulse shielding as shielding materials, in chemical and biological sensors as electrodes, in flexible electronics as electrodes and sensors, in post-CMOS nanoelectronic devices as interconnects, thermal applications as heat shielding materials in hypersonics and electronics, in structural composites, filtration as filters for water, biologics, in eyewear such as an eyewear sidearm that stores electrochemical energy and which can be used for laser projection application, and the like. Various aspects of the present invention provide graphene derived from the photothermal pyrolysis of a screen-printed exemplary precursor materials—such as cPAN and/or poly (BZ)—coated on flexible polyimide and targeted for printed and flexible electronics applications.

### EXAMPLES

Various aspects of the present invention can be better understood by reference to the following Examples which are offered by way of illustration. The present invention is not limited to the Examples given herein.

A method for fast and efficient preparation of graphene via photothermal pyrolysis of thin precursor films at ambient conditions in millisecond timeframe includes involves photothermal pyrolysis of unpatterned, print-patterned, and imprint-patterned graphene precursor films, using high intensity pulsed light from a xenon flash lamp, operating in air at room temperature.

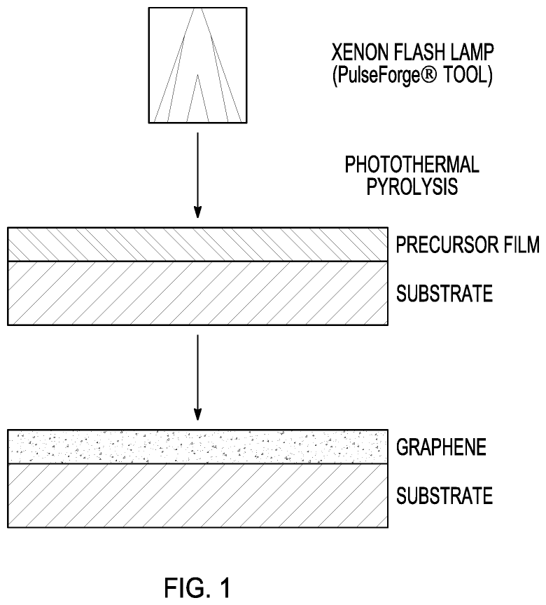

FIG. 1 shows the scheme for the process. By localizing light absorption to the precursor films during photothermal treatment, the process can be carried out at ambient temperature, enabling the preparation of high-quality graphene and graphene composites on any substrate, including thermally sensitive substrates, and without the need for a catalyst over large areas. The use of patterned films deposited using screen printing or additive approaches yields 2-dimensional patterned graphene materials directly. Nanoimprint patterning of the precursor films before photothermal processing can directly yield architected 3-dimensional surfaces with features spanning nanoscale to microscale dimensions. The process produces high-quality pristine graphene and graphene composites, depending on the starting precursor.

Given that the source of the radiation is pulsed, with duration (on the order of milliseconds) shorter than the thermal equilibrium time of the preceramic polymers and the substrate, the precursor film will quickly heat up and pyrolyze before it can transfer significant energy to the substrate. Ideal pyrolysis conditions are dependent on the precursor film, its absorption cross-section, film thickness, substrate type, and additive type/content, if any. The exposure energy delivered to the sample can be adjusted by varying the discharge voltage and pulse duration. The ability to independently tune the pulse duration and intensity provides independent control over both the power and energy delivered to the sample. The choice of photonic processing using xenon flash lamp sources rather than lasers offers several advantages, including reduced cost and complexity, improved efficiency in converting electrical energy to light, and scalability for large area processing without rastering.

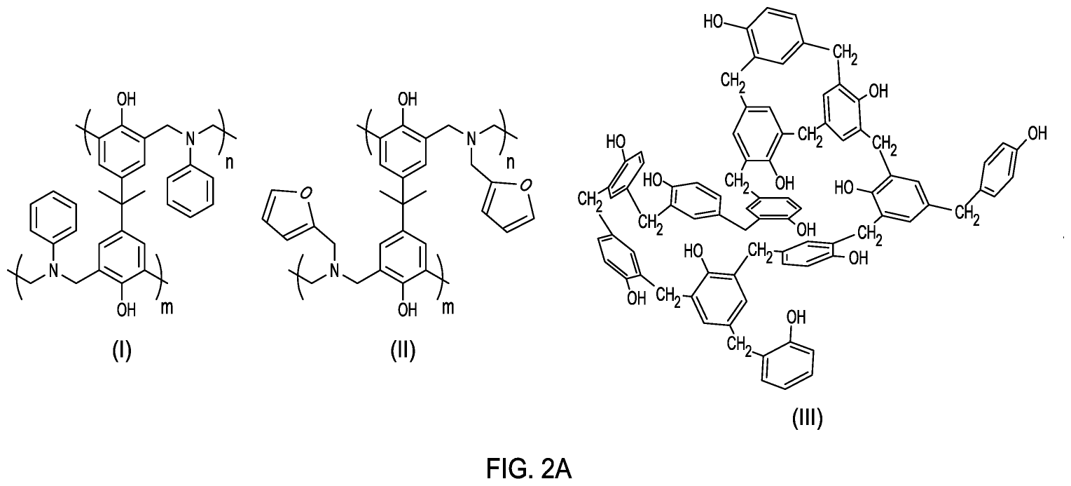

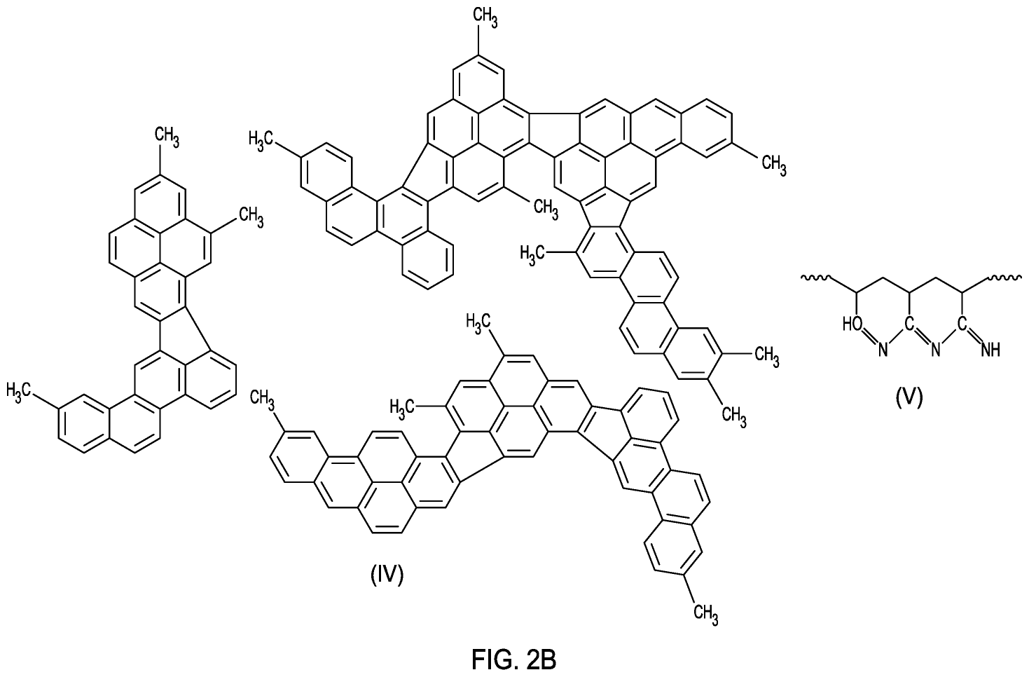

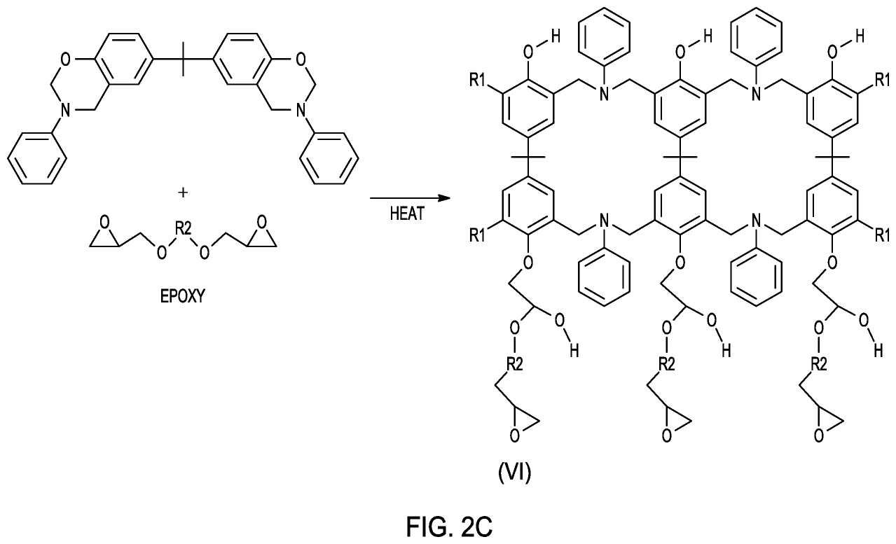

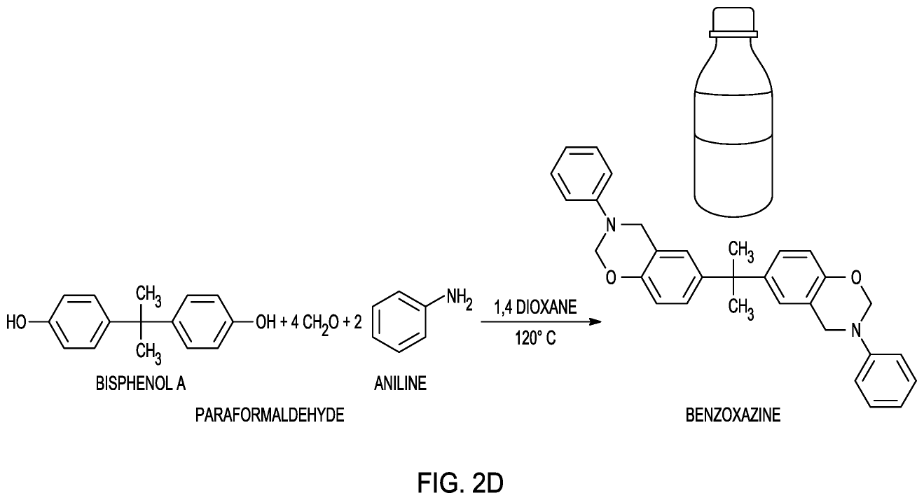

The polymeric graphene precursor has an absorption profile that overlaps a portion of the emission spectrum of the xenon flash lamp, with peak intensity at 400-600 nm. The n-π* (R-band) is the most relevant electronic transition corresponding to this wavelength region, and materials possessing moieties able to be excited by radiation within a significant portion of the emission spectrum of the xenon flash lamp will perforce be successfully pyrolyzed when irradiated with pulses of sufficient intensity and power density. While we highlight the use of xenon flash lamps here, other broadband, high-intensity pulsed sources may also be used to photothermally pyrolyze appropriate precursors. Examples of appropriate precursors include substances containing disubstituted benzenes such as nitroaniline, nitro phenol, biphenyls (where two aromatic rings are in conjugation); benzenes substituted with chromophores such as nitrobenzene, benzaldehyde, acetophenone, nitrobenzene, biphenyls); and polynuclear aromatics with high aromatic content such as pyrene, pentacene, anthracene, tetracene. Select representative examples of precursor resins, shown in FIGS. 2A-2C, include but are not limited to the following: poly(3-phenyl-2,4-dihydro-1,3-benzoxazine) or poly(phenyl benzoxazine) (I), poly(3-furanyl-2,4-dihydro-1,3-benzoxazine) or poly(furanyl benzoxazine) (II), poly(phenol-co-formaldehyde) or resol (III), oligomers of pyrene pitch (IV), cyclized polyacrylonitrile (V), polyaniline, thermosetting resin networks (VI) formed from blending and crosslinking polybenzoxazines with epoxies such as furfuryl diglycidyl ether of bis-phenol-A (where R2 is bisphenol-A, and the epoxy is diglycidyl ether of bisphenol-A) and furan diepoxy, and the like. Other examples include pristine carbon fiber and/or polyaniline (e.g., having the structure -(phenyl-NH)ₙ— wherein the connectivity of the phenyl ring in the polymer backbone is 1,4 (para)).

Conventional methods, except electrochemical reduction and CVD approaches, are not scalable to large scale production. Most of them are extremely energy intensive, are operated under harsh conditions, are expensive and are very slow to execute. Various aspects of the present invention overcome all these shortcomings by using a high-intensity pulsed xenon flash lamp in air at ambient conditions of room temperature atmospheric pressure to pyrolyze appropriate precursors in milliseconds. The milliseconds duration of the radiation pulse is shorter than the thermal equilibrium time of the precursors, enabling pyrolysis of the precursors and formation of high-quality graphene before significant energy transfer to the substrate, making this process uniquely amenable to graphene preparation on or adjacent to thermally sensitive materials. Rapid precursor pyrolysis and phase transformation during flash lamp processing, even in air, limits oxidation of the resulting graphene.

### Example 1. Synthesis of Exemplary Precursor Materials-Benzoxazine Monomer and Polyaniline

Benzoxazine monomer can be synthesized via a one pot chemical reaction using bisphenol A, aniline, and paraformaldehyde following the molar ratio of 1:2:4, as illustrated in FIG. 2D, Bisphenol A and aniline are introduced into a two-neck round bottom flask fitted with a reflux condenser, and resulting solution stirred for 30 minutes at room temperature to ensure homogenous mixing. Next, with the aid of an ice bath, the temperature of the mixture is reduced to 5° C., following which a dispersion of stoichiometric amount of paraformaldehyde dispersion in dioxane is added to the bisphenol A and aniline reaction mixture, dropwise. Then, resulting reaction mixture is heated at 60° C. for 1 hr in a silicone oil bath, followed by heating at 120° C. for an additional 5 hr, accompanied by constant stirring and refluxing. The change in the color of the reaction solution from milky white to transparent orange confirms the conversion of the reagents to benzoxazine monomer. Residual dioxane solvent can be removed from benzoxazine monomer by heating the product mixture at 130° C. for 2 hr, following which the product is cooled to room temperature to obtain pure benzoxazine monomer, which can thus be used as is without any further processing. The yield of the reaction is 90%.

Polyaniline (PANI) was electrochemically grown (electrodeposited) on conducting carbon fiber substrate using three electrodes set up as described in various literatures previously, using carbon fiber as working electrode, with Platinum wire as counter electrode, and Ag/AgCl as a reference electrode. Electrodes were immersed into aqueous solution containing 0.3 M Aniline and 1 M HCl as an electrolyte. A constant current of 10 mA was applied for 10 minutes resulting in the uniform growth of PANI on carbon fiber. Post deposition, PANI on CF was thoroughly washed with deionized water to remove the excess electrolyte followed by removal of drying at 100° C. for 1 hr.

### Example 2. Photothermal Pyrolytic Processing of Exemplary Unpatterned Precursor Film Materials

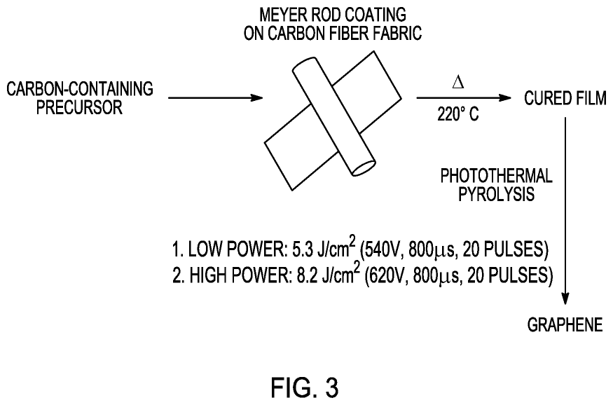

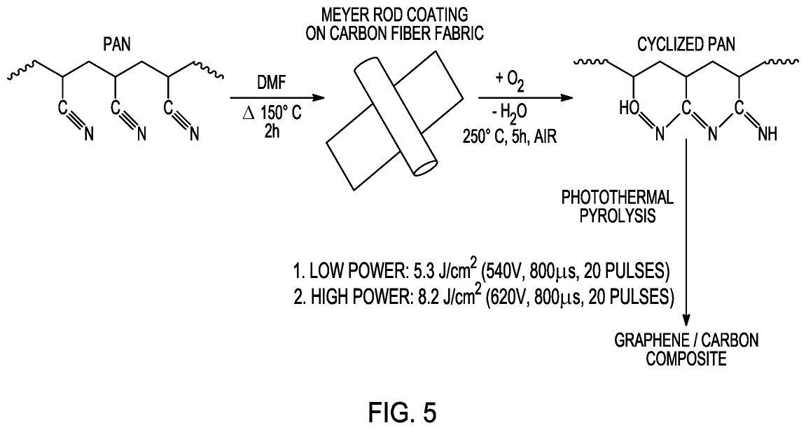

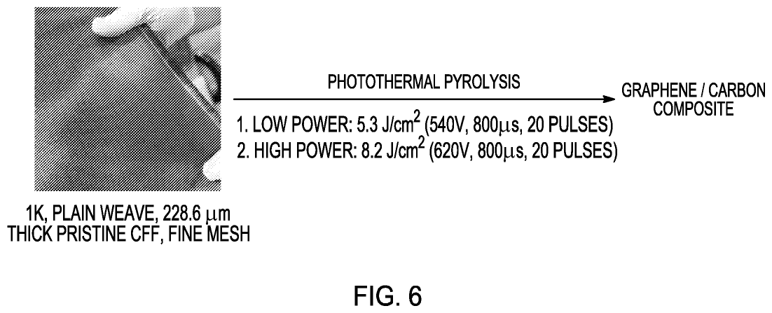

FIG. 3 through FIG. 5 are schematics of the processing sequence for the photothermal pyrolysis of two exemplary unpatterned precursor films of polybenzoxazine and cyclized polyacrylonitrile coated on carbon fiber. FIG. 6 shows the processing scheme for the photothermal pyrolysis of pristine carbon fiber. Solutions of the precursor materials in appropriate solvent and appropriate concentrations are first formulated for use in photothermal processing. For the benzoxazine exemplary precursor materials and blends of benzoxazine with epoxy precursor materials, the solution is made in dioxane to a concentration of 1.0 g/mL. FIG. 5 shows the photothermal processing sequence for cyclic polyacrylonitrile (another exemplary precursor material). Polyacrylonitrile solution in dimethyl formamide and appropriate concentrations are first formulated for use in photothermal processing.

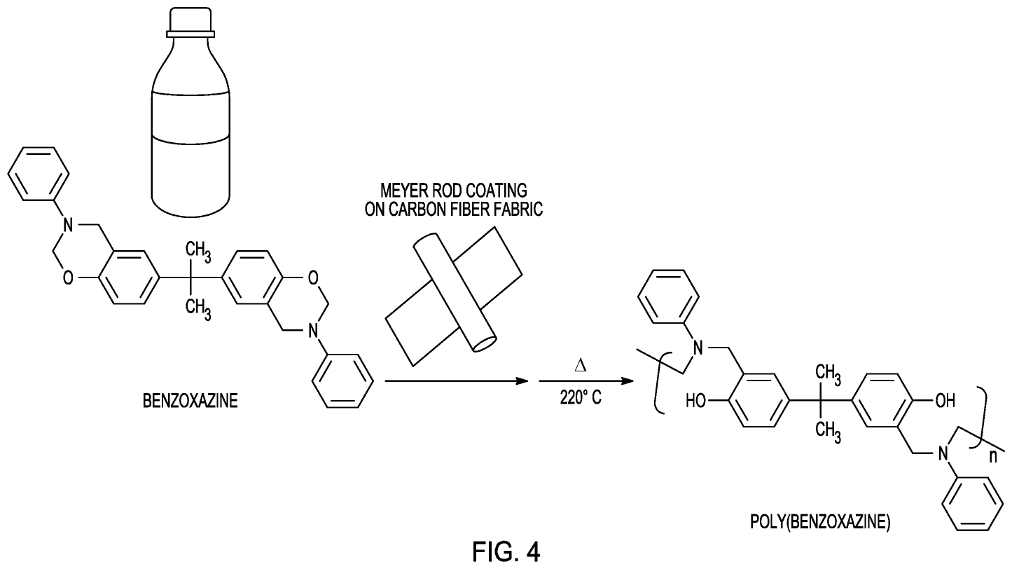

The processing sequence for unpatterned films begins with films of precursor being coated on both sides of appropriates substrates, for example carbon fiber substrate (10 cm×10 cm in dimension), using a Meyer rod (#20) to a thickness of 5-8 microns, dried at room temperature and then thermally cured in a nitrogen-filled oven maintained at 220° C. for 24 hrs. Curing crosslinks the precursor monomer and converts it to corresponding polymer, as illustrated in FIG. 4 for the crosslinking of benzoxazine monomer to the exemplary polybenzoxazine precursor.

Next, the unpatterned and patterned films are subjected to photothermal pyrolysis using a xenon flash lamp in a PulseForge 1300 tool ((PulseForge® 1300 Xenon Lamp system, Novacentrix, Austin, TX, USA)). The dried and crosslinked PCP films on their respective substrates are first loaded onto a stainless-steel chuck positioned under the center of the xenon flash lamp of the tool. The lamp must be positioned 15 mm above the sample to ensure uniform energy distribution within the PCP film to be irradiated. It is important to control the rates and mechanisms by which organics and solvents in the PCP films are removed as gaseous products during the pyrolytic transformation of the precursors to ensure uniform densification, prevent retention of impurities, and/or prevent the creation of gas generated flaws such as pores. To this end, samples must first be irradiated with 20 pulses (0.5 Hz frequency, 800 us pulse length, and 540 V voltage) of areal energy density of 5.3 J/cm² to volatilize residual solvent and low molecular weight constituents of the film that are still left in the films following thermal curing in vacuum oven. Next, the samples must be irradiated 20 high power pulses (1.0 Hz frequency, 800 us pulse length, and 620 V voltage) of areal energy density of 8.2 J/cm² to pyrolyze them.

The photothermal processing of PANI on CF was performed involving two steps similar to that of polybenzoxazine based system. PANI on CF allowed the photothermal processing without any requirement of high temperature crosslinking as it underwent crosslinking during the carbonization enabling the process to be more sustainable and less energy intensive. Samples were first irradiated with low energy dose of 2.6 J/cm² (400V, 800 μs, 1 Hz frequency) for 10 pulses to remove the organic residues followed by high energy dose of 8.91 J/cm² (630V, 800 μs, 1 Hz frequency) for 10 pulses to completely transform the PANI into graphene.

### Example 3. Photothermal Pyrolytic Processing of Exemplary Patterned Precursor Film Materials

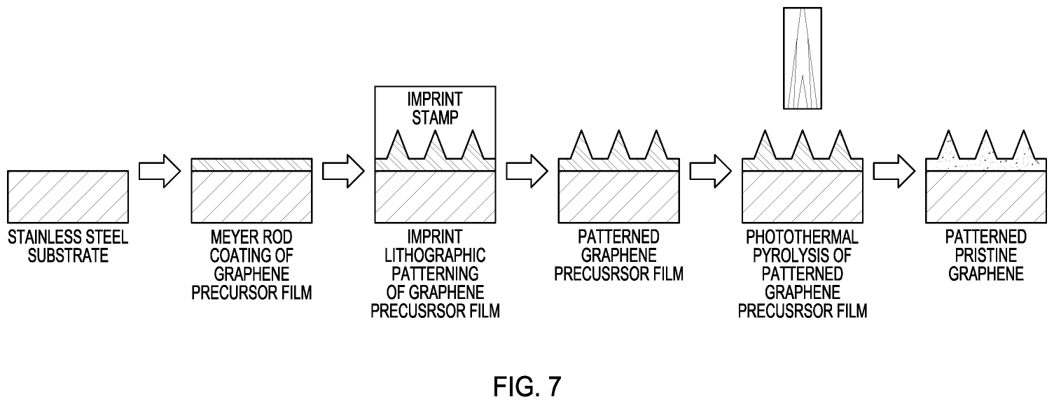

The processing sequence for patterned films (FIG. 7) involves soft lithographic imprint patterning of appropriate polymeric films coated on suitable substrates including silicon wafers and stainless-steel foils, using fluorinated solvent permeable patterned poly(dimethyl siloxane) stamps, while simultaneously curing the films at appropriate temperatures. Next, the cured films are subjected to photothermal pyrolysis in air using high intensity xenon flash lamp to yield patterned graphene structures, without the use of a catalyst. The photothermal pyrolytic processing condition involved irradiating the cured sample with 70 pulses (1.0 Hz frequency, 500 us pulse length, and 540 V voltage) of areal energy density of 5.3 J/cm². Fluorination of the stamp ensures a smooth release of the stamp at the end of the imprint process, without damaging the imprinted features. Thermal curing at 220° C. in an oven supplied with nitrogen gas, yields structures that are structurally stable to photothermal pyrolysis in air at temperatures of up to 1500° C. Structures of various geometries including lines, holes, trenches, etc., and length scales ranging from nanometers to millimeters, are readily realized with this technique in a few minutes. Suitable precursor polymers have absorption spectra with peak maxima that overlaps the emission spectrum of xenon flash lamp, and these include polybenzoxazine, phenol-formaldehyde resin, and others.

### Example 4. Photothermal Pyrolytic Processing of Exemplary Screen-Printed Precursor Film Materials

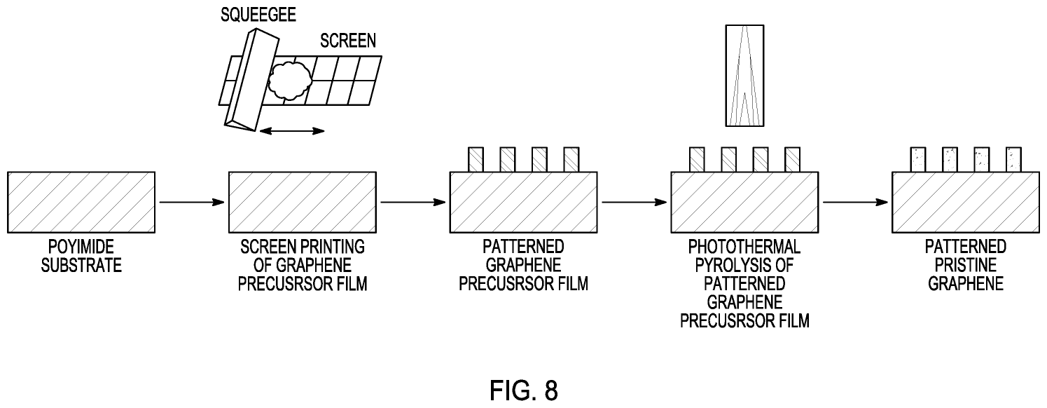

The processing sequence for screen-printed films is shown in FIG. 8, and it involves dispensing of an appropriate amount of neat viscous solution of precursor film on a screen disposed over an appropriate high temperature substrate such as polyimide film, printing the image of the screen on the substrate by forcing the solution through the screen with the application of force. Next, the film is thermally cured for 24 hours at an appropriate temperature, which in the case of polybenzoxazine, is at 220° C. in an oven supplied with nitrogen. For poly(acrylonitrile) precursor, the screen-printed film is first cured at 150° C. in an oven supplied with air, followed by heating the sample at 250° C. overnight to cyclize the linear polyacrylonitrile. Thermal curing of screen-printed precursor films of polybenzoxazine at 220° C. and cyclization of polyacrylonitrile at 250° C. yield structures that are structurally stable to photothermal pyrolysis in air at temperatures of up to 1500° C.

Next, the cured or cyclized precursor film is subjected to photothermal pyrolysis in air to convert it to graphene structures, without the use of a catalyst. The photothermal pyrolytic processing condition involved irradiating the cured sample with 20 pulses (1.0 Hz frequency, 500 us pulse length, and 490 V voltage) of areal energy density of 2.5 J/cm². Photothermal pyrolysis using such low power pulses ensures the maintenance of structural integrity of the screen-printed features. Otherwise, the features might be damaged.

### Example 5. Materials Characterization of Exemplary Unpatterned Precursor Polybenzoxazine and Graphene/Carbon Fiber Composites Derived from its Photothermal Pyrolysis

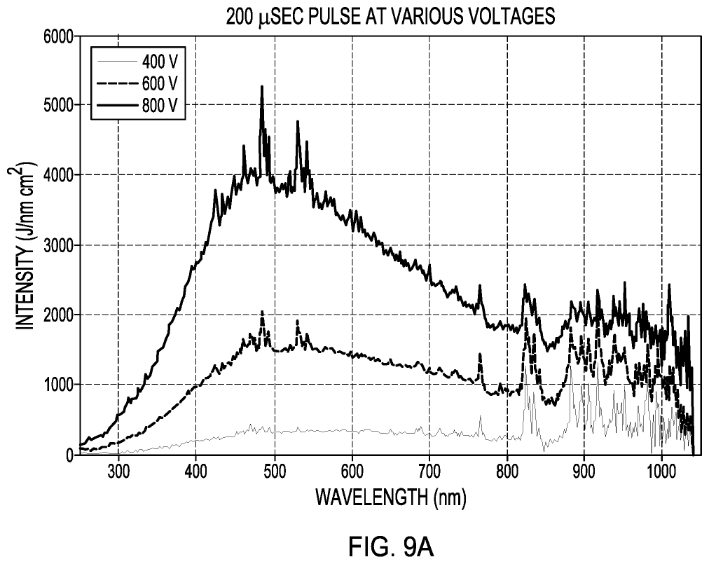

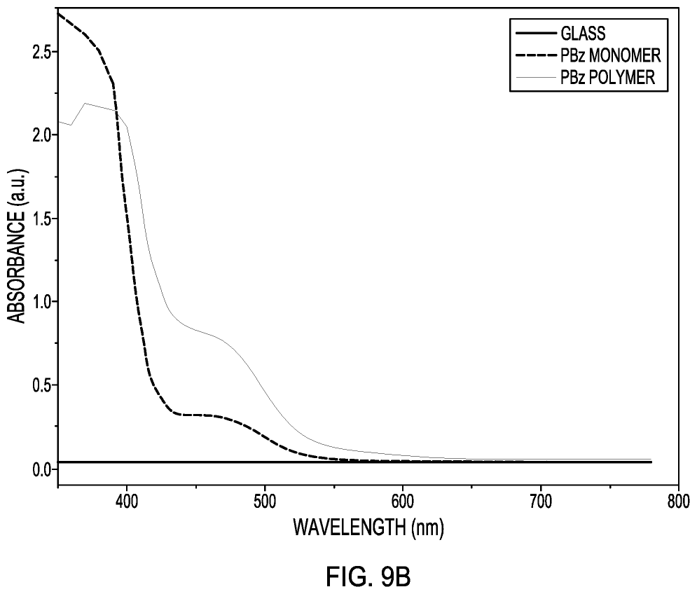

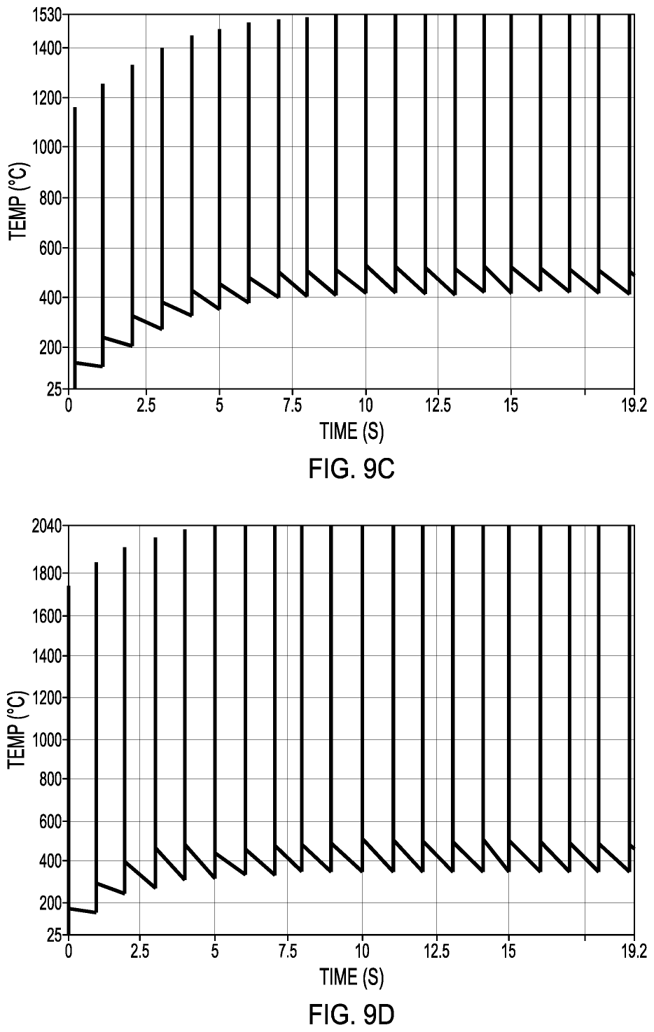

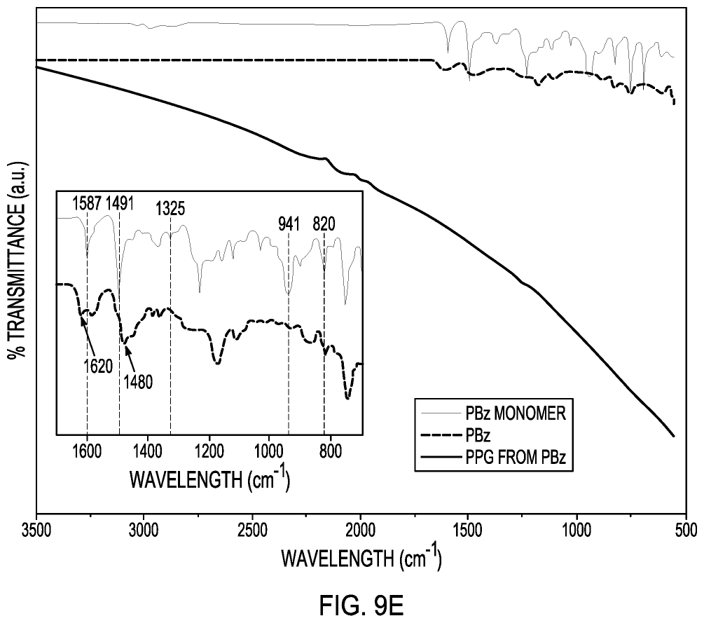

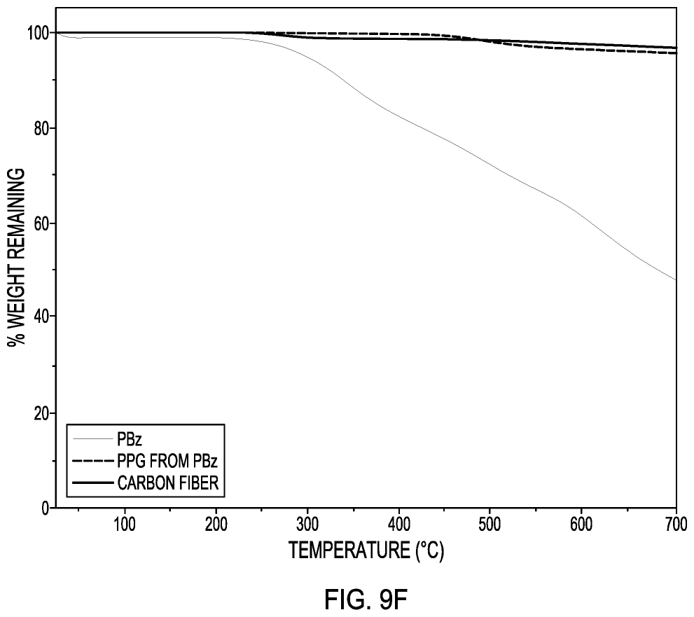

Polybenzoxazine is a moderate char yield polymer, with absorbance spectrum that overlaps the maximum intensity of xenon lamp emission spectrum (FIGS. 9A and 9B). UV/Vis/NIR absorption spectra of polybenzoxazine film scoated on stainless steel substrates were collected in reflectance mode over a wavelength range from 200 nm to 1200 nm using Lambda-1050 UV/Vis/NIR spectrophotometer (Perkin-Elmer Corporation, Boston, M.A., U.S.A). Samples were spin coated on glass substrate to perform the measurement. When photothermally pyrolyzed, the film can reach temperatures in excess 1530° C. and 2040° C., depending on the pulse power modulation (FIGS. 9C and 9D). IR spectroscopy was used to monitor the structural changes in the film as a function of processing. Infrared absorption spectra of the samples were obtained using a Frontier 1300 attenuated total reflectance Fourier transform infrared spectrometer (Perkin-Elmer Corporation, Boston, MA, U.S.A) in the range of 3200-500 cm⁻¹. The samples consisted of powders of composites scraped off from carbon fiber substrates following pyrolysis. Disappearance of monomeric oxazine ring and tri-substituted benzoxazine at 941 cm⁻¹ 1491 cm⁻¹ peaks, respectively, in the FTIR spectra confirmed the complete transformation of benzoxazine monomer to polymer and thermal curing of the polymer (FIG. 9E). The lack of structure in the spectrum of the composite confirmed that the precursor material was fully pyrolyzed and converted to carbonaceous composite (FIG. 9E). Thermogravimetric analysis was carried out on Q50 TA instruments in the temperature range of 25-700° C. at 10° C. min-1 in nitrogen atmosphere. Thermal gravimetric analysis confirmed the conversion of the polybenzoxazine to carbonaceous composite (FIG. 9F).

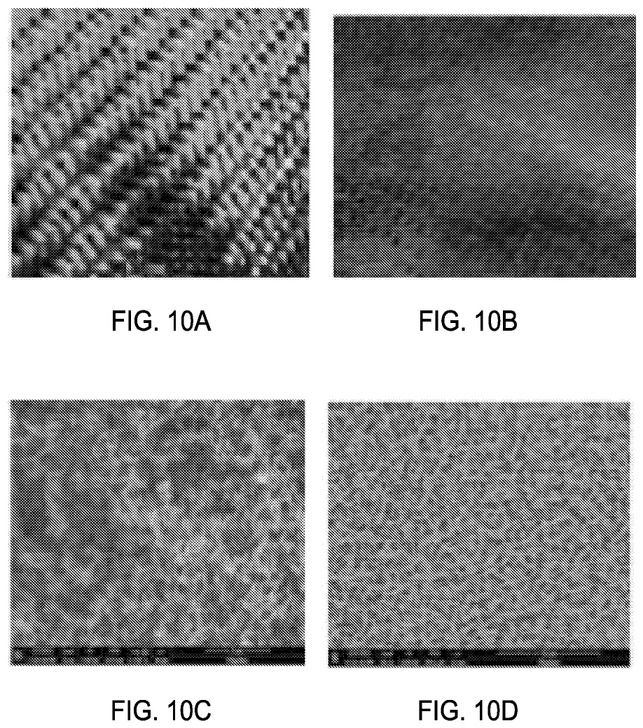

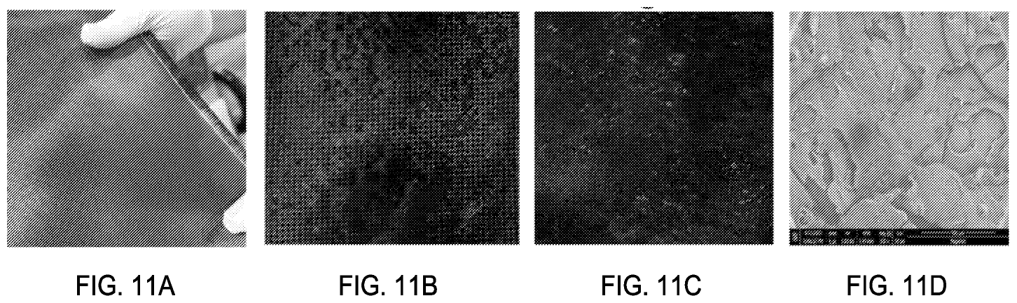

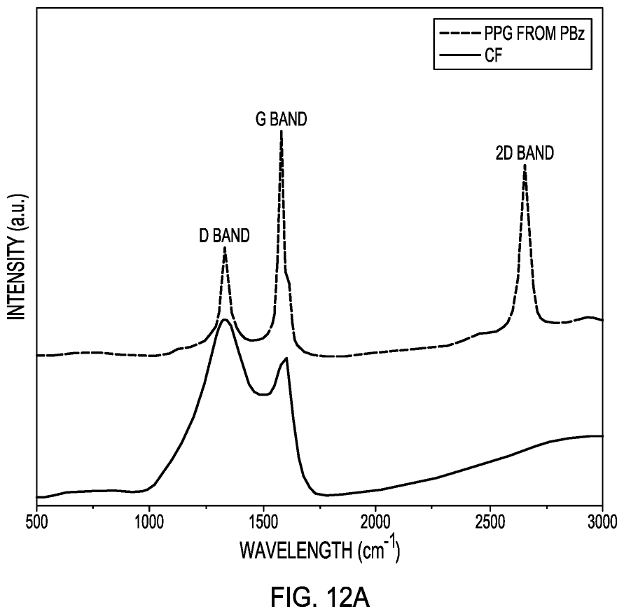

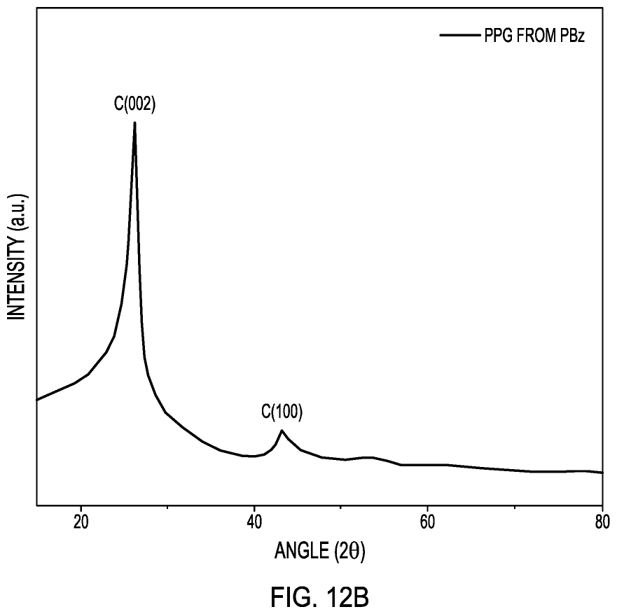

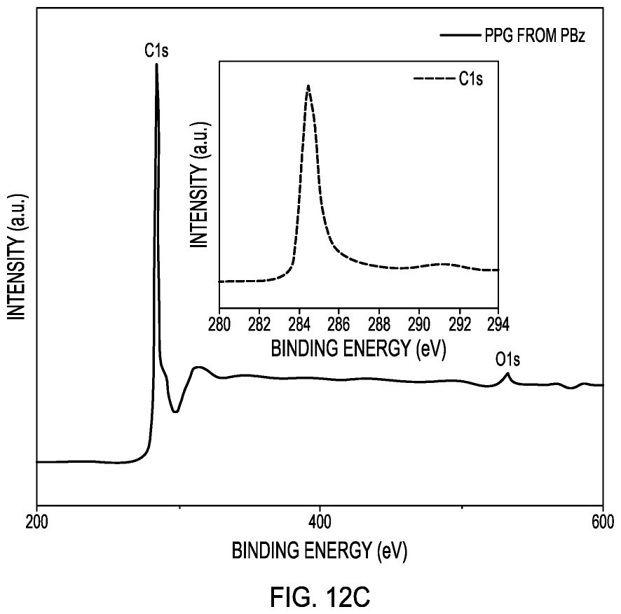

Surface morphologies of samples were analyzed using field emission scanning electron microscope (FEI Magellan 400 XHR SEM and FEI Helios Dual Beam FIB SEM). High-resolution transmission electron microscopic (HRTEM) analysis of the samples was done with JEOL JEM-2200 OFS energy filtered transmission electron microscope, using 200 kV accelerating voltage. The samples consisted of powders of graphene composites scraped off from carbon fiber substrates following pyrolysis. Raman spectroscopy was used to investigate phase ordering and phase transformations of the composites. Raman spectra of the samples were recorded on a ThermoScientific DXR Smart Raman spectrometer (ThermoFisher Scientific, Waltham, MA, U.S.A) with an excitation laser wavelength of 633 nm and laser power of 5 mW, spot diameter of 3.1 μm, and sample exposure of 5s, at room temperature. FIGS. 10A-D an show optical image of cured poly(benzoxazine) on carbon fiber fabric (FIG. 10A) and SEM images of composites derived from the photothermal pyrolysis of the cured poly(benzoxazine) (FIGS. 10C, 10D). FIGS. 11A-C show optical images of pristine carbon fiber fabric (FIG. 11A), carbon fiber/graphene composite obtained after one layer of coating and pyrolysis (FIG. 11B), as well as a 1093 μm thick carbon fiber/graphene composite, obtained after two layers of coating and pyrolysis of the precursor film (FIG. 11C). FIG. 11D shows SEM images of the composite in FIG. 11C. The composite has a microporous surface morphology. The Raman spectra obtained on the photothermally-pyrolyzed samples show characteristic graphitic bands near 1582 cm⁻¹ (Graphitic, G-band) and 1350 cm⁻¹ (Disorder, D-band) (FIG. 12A). The ratio of the intensity of the D-band relative to the G-band (I_{D}/I_{G} ratio) is a good measure of the quality of the graphitic carbons in the sample. The I_{D}/I_{G} ratio is 0.46. As this ratio is less than unity, the sample has high degree of order and is of a high graphitic phase. The peak near 2700 cm⁻¹ (2D-band) is an overtone of the D-band, and it is also characteristic of graphite, specifically, graphitic ordering of free carbon along the free axis. That this peak can be fitted with a single Lorentzian peak is indicative of the presence of high-quality graphene in the sample. The size of this peak relative to the G-peak is also a good measure of the number of graphene layers present in the sample. The I_{2D}/I_{G} ratio is 0.64, which is suggestive of the presence of few layer graphene in the sample.

X-ray diffraction pattern confirms the composite to be highly ordered (FIG. 12B). Crystallinity of photothermally derived graphene composite was determined using X-ray diffraction (PANanalytical X'Pert X-ray diffractometer) with Cu Kαα radiation of wavelength 1.54 Å at the voltage of 45 kV and current of 40 mA. X-ray Photoelectron Spectroscopy (XPS) of graphene composites was performed using Physical Electronics Versa Probe II instrument equipped with a monochromatic Al kα x-ray source (hν=1,486.6 eV) and a concentric hemispherical analyzer. All the peaks were corrected using the reference C1s spectra at 284.5 eV. XPS spectrum indicates the presence of C1s at binding energy of 284.5 eV, which is indicative of Sp² hybridized carbon, characteristic of graphene and graphitic structures (FIG. 12C). Additionally, XPS shows that the atomic composition of the composite is 99.1% C, 0.9% O, suggesting a purely carbonaceous composite.

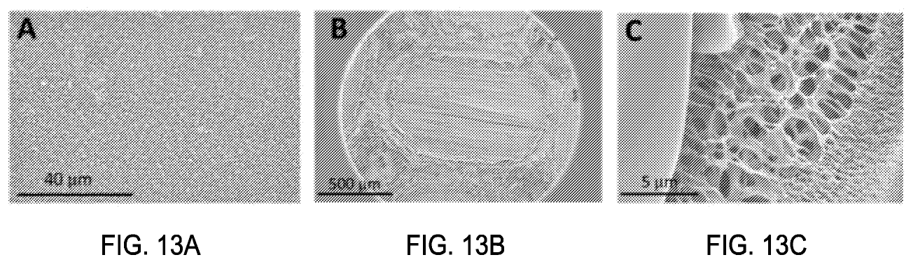

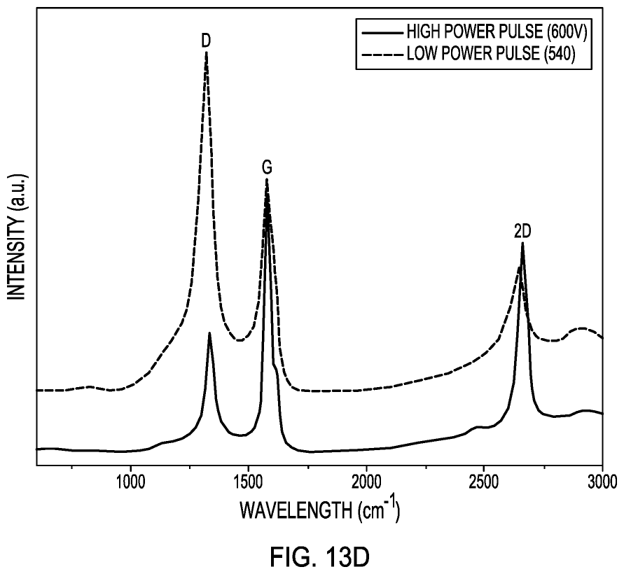

FIGS. 13A-D show pulse power modulation of graphene/carbon composite microstructure and phase ordering. The low power process leads to complete carbonization, with significant defectivity, highly porous and rather low-quality graphene composite. The high-power process is associated with reduced defectivity, decreased porosity and high-quality graphene. I_{D}/I_{G} of spectrum obtained with high power pulse process=0.46, I_{2D}/I_{G} of spectrum obtained with high power pulse process=0.65, I_{D}/I_{G} of spectrum obtained with low power pulse process=1.29, I_{2D}/I_{G} of spectrum obtained with low power pulse process=0.57. Low power pulse process: 20 pulses (0.5 Hz, 800 μs pulse length, and 540 V voltage) of areal energy density of 5.3 J/cm² per pulse, corresponding to a total areal energy density of 106 J/cm². High power pulse process: 20 pulses (1.0 Hz, 800 μs pulse length, and 620 V voltage) of areal energy density of 8.2 J/cm² per pulse, corresponding to a total areal energy density of 164 J/cm².

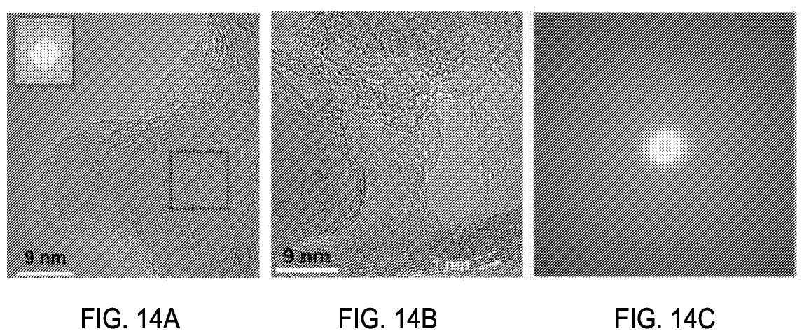

Transmission electron microscopy was used to investigate the microstructure of the composite. With a hexagonal lattice having a D-spacing of ˜0.33 nm, obtained via Fourier Transform further confirmed the presence of graphene in the composite (FIGS. 14A-C). In contrast, the TEM of amorphous carbon (FIG. 14C) shows no structure of any kind.

### Example 6. Materials Characterization of Exemplary Patterned Precursor Polybenzoxazine and Graphene/Carbon Fiber Composites Derived from its Photothermal Pyrolysis

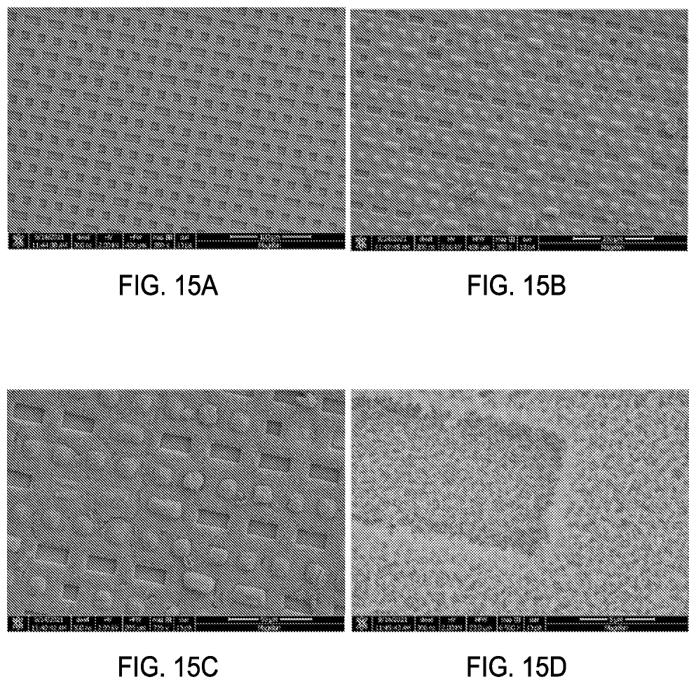

FIGS. 15A-D shows SEM images of imprinted and thermally cured structures, and graphene features derived from them upon photothermal pyrolysis in air. FIG. 15 B through FIG. 15D show dimensionally stable graphene features, including include lines, square holes, and trenches, with the patterned features decorated with graphene flake and platelets (grey in color). Some of the imprinted features are covered by graphene flakes and platelets, if the size of the features is smaller than that of the graphene flakes and platelets.

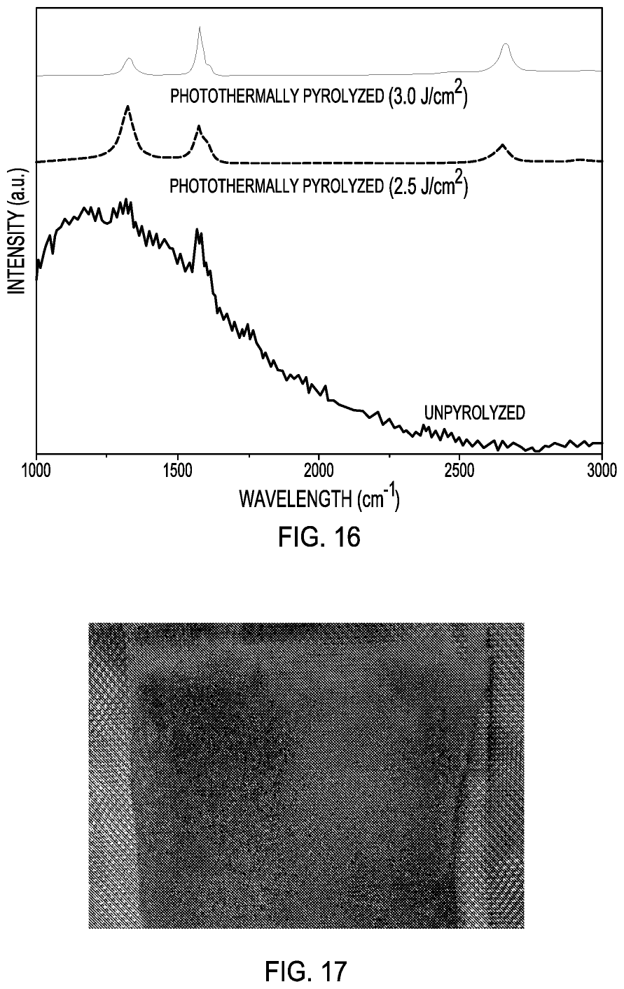

FIG. 16 shows Raman spectra of imprinted and thermally cured structures, and graphene features derived from them upon photothermal pyrolysis in air, as a function of irradiation pulse energy density, using 70 pulses (1.0 Hz, 500 μs pulse length, and 520 V voltage) of areal energy density of 2.5 J/cm² per pulse (corresponding to total areal energy density of 175 J/cm²); 70 pulses (1.0 Hz, 500 μs pulse length, and 560 V voltage) of areal energy density of 3 J/cm² per pulse (corresponding to total areal energy density of 210 J/cm²). The unpyrolyzed sample was not photothermally treated. The spectra obtained on the photothermally-pyrolyzed samples show characteristic graphitic bands near 1582 cm⁻¹ (Graphitic, G-band) and 1350 cm⁻¹ (Disorder, D-band). The ratio of the intensity of the D-band relative to the G-band is less than unity in the sample pyrolyzed with a total pulse energy density of 210 J/cm², indicating that the sample has high degree of structural order and is of a high graphitic phase quality. The ratio of the intensity of the D-band relative to the G-band is greater than unity in the sample pyrolyzed with a total pulse energy density of 170 J/cm², indicating that the sample has high degree of structural disorder and is of a low graphitic phase quality. The photothermally-pyrolyzed samples also have peak 2D peaks near 2700 cm⁻¹, which also characteristic of graphite, specifically, graphitic ordering of free carbon along the free axis. That this peak can be fitted with a single Lorentzian peak is indicative of the presence of high-quality graphene in these samples. That the ratio of the 2D-peak to the G-peak is less than unity is in the sample photothermally pyrolyzed with 210 J/cm² pulses, is suggestive of the presence of few layer graphene in the sample. The quality of the obtained graphene improves with the pulse power density used in the pyrolysis of the precursor film. In contrast, the unpyrolyzed sample lacks 2d peak; it has very broad D-peak and a poorly defined G-peak.

### Example 7. Materials Characterization of Graphene/Carbon Fiber Composite Derived from the Photothermal Pyrolysis of an Exemplary Unpatterned Precursor-Cyclized Polyacrylonitrile

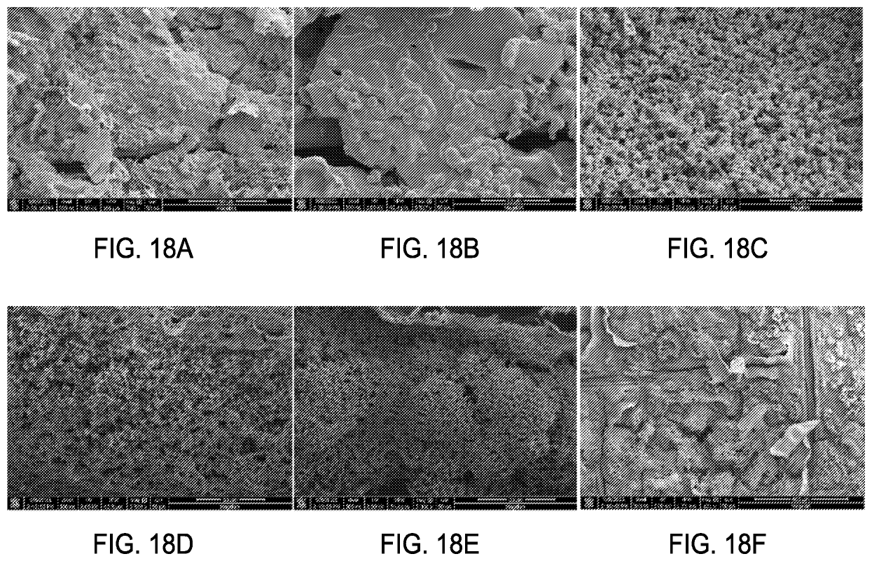

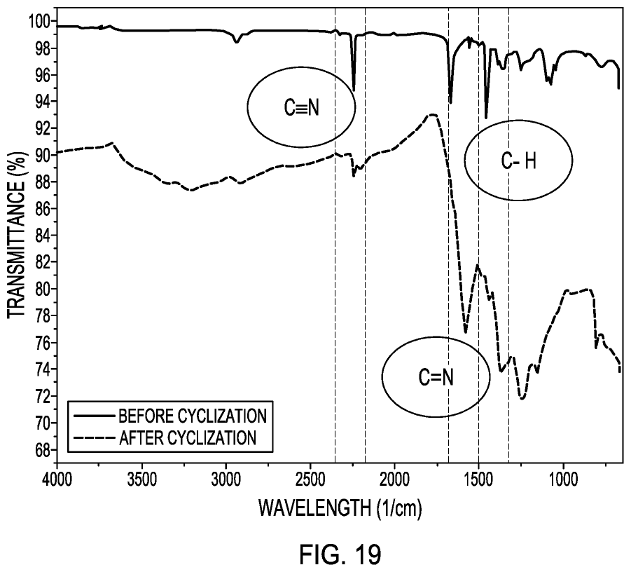

While cyclized polyacrylonitrile has an absorbance spectrum that overlaps the maximum intensity of xenon lamp emission spectrum, linear polyacrylonitrile does not. This explains the reason for why cyclized polyacrylonitrile is readily pyrolyzed with the xenon flash and its linear form is not. FIG. 17 shows optical image of graphene/carbon fiber composite derived from the layer-by-layer coating, followed by photothermal pyrolysis of cyclized polyacrylonitrile film after one round of coating and pyrolysis. The surface morphology of the composite was studied with scanning electron microscopy. FIGS. 18A-F show SEM images of graphene/carbon fiber composite derived from the layer-by-layer coating, followed by photothermal pyrolysis of cyclized polyacrylonitrile film after one round of coating and pyrolysis. The composite has a microporous surface morphology. IR spectroscopy was used to monitor the structural changes in the film during the cyclization process (FIG. 19). FTIR spectra confirms completion of cyclization reaction of polyacrylonitrile, as shown by the disappearance of nitrile group C≡N peak at 2245 cm⁻¹, appearance of C═N peak at 1596 cm⁻¹ and appearance of C—N single bond peak at 1257 cm⁻¹ in cyclized polyacrylonitrile spectra. The lack of structure in the spectra of the composite of the composites derived pyrolysis confirmed that the precursor material was fully pyrolyzed and converted to carbonaceous composite.

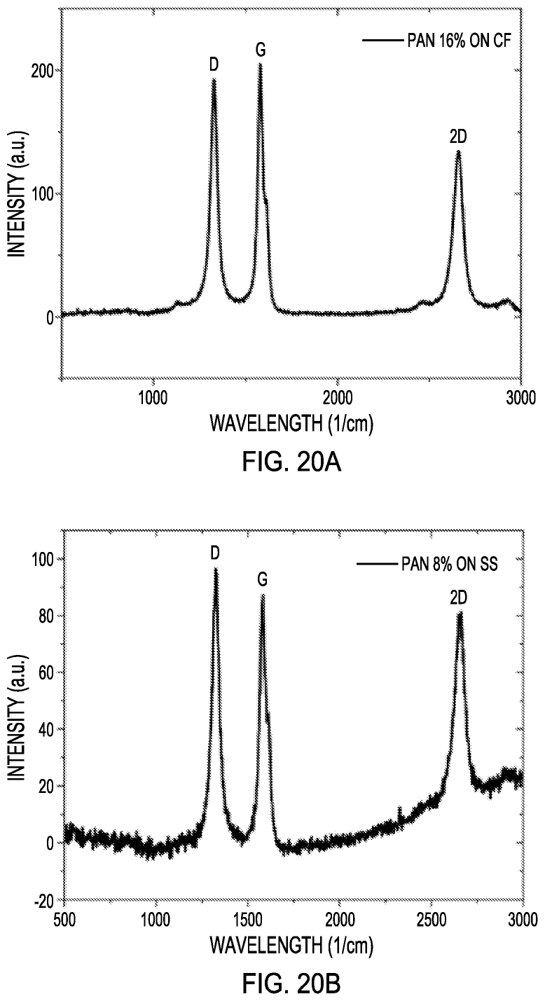

Raman spectroscopy was used to investigate phase ordering and phase transformations of the composites as a function of substrate type: carbon fiber and stainless steel. Raman spectra (FIGS. 20A-B) on composites obtained on both carbon fiber and stainless-steel substrates confirm the composites to contain graphene of rather good quality given the presence of 2D peak at 2650 cm⁻¹ and the fact the ratio of the intensity of disorder band at 1350 cm⁻¹ and graphitic band at 1550 cm⁻¹ is rather low I_{D}/I_{G} ratio slightly <1, particularly after one round of layer-by-layer coating and pyrolysis on carbon fiber substrate. That the ratio of the intensity of disorder band at 1350 cm⁻¹ and graphitic band at 1550 cm⁻¹ with the I_{D}/I_{G} ratio slightly greater than 1.0 for the composite obtained on stainless steel substrate suggests perhaps that the stainless-steel substrate is not as efficient as carbon fiber in forming high quality graphene. That the 2D peak obtained on both substrates can be fitted with a single Lorentzian peak is indicative of the presence of high-quality graphene in the samples. The size of this peak relative to the G-peak is also a good measure of the number of graphene layers present in the sample. That the ratio of the 2D-peak to the G-peak is slightly less than unity in the samples obtained on the two substrates is suggestive of the presence of few layer graphene in the samples.

### Example 8. Materials Characterization of Exemplary Screen-Printed Precursor Cyclized Polyacrylonitrile and Graphene/Carbon Fiber Composites Derived from its Photothermal Pyrolysis

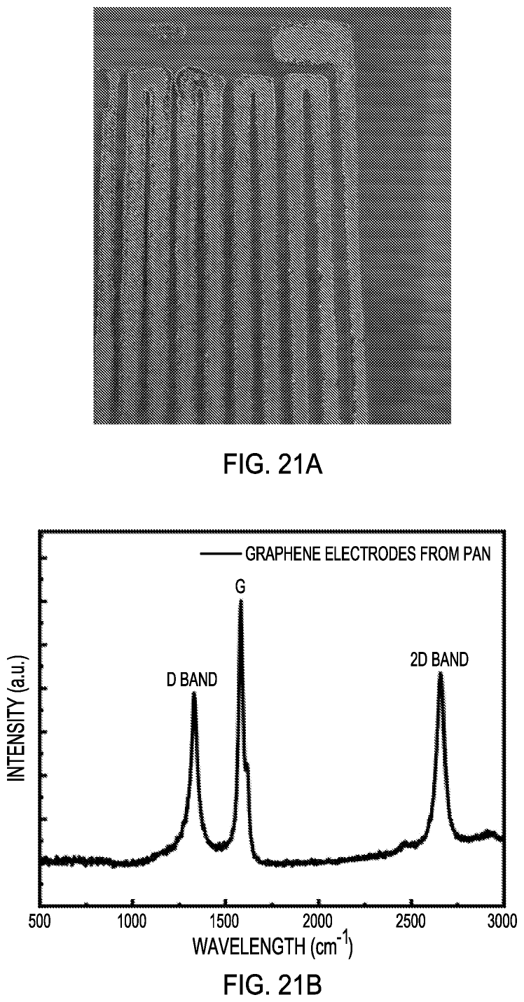

FIGS. 21A-B shows optical image (FIG. 21A) and Raman spectra (FIG. 21B) of dimensionally stable polyimide/graphene composite electrode structures derived from the photothermal pyrolysis in air of screen-printed and thermally cured cyclized polyacrylonitrile electrode structures. I_{D}/I_{G} of spectrum=0.63, I_{2D}/I_{G} of spectrum obtained with high power pulse process=0.71. Photothermal process: 20 pulses (1.0 Hz, 500 μs pulse length, and 490 V voltage) of areal energy density of 2.5 J/cm² per pulse, corresponding to total areal energy density of 50 J/cm²). The Raman spectra obtained on this sample shows characteristic graphitic bands near 1582 cm⁻¹ (Graphitic, G-band) and 1350 cm⁻¹ (Disorder, D-band) (FIG. 21B). The ratio of the intensity of the D-band relative to the G-band (I_{D}/I_{G} ratio) is a good measure of the quality of the graphitic carbons in the sample. The I_{D}/I_{G} ratio is 0.63. As this ratio is less than unity, the sample has high degree of order and is of a high graphitic phase. The peak near 2700 cm⁻¹ (2D-band) is an overtone of the D-band, and it is also characteristic of graphite, specifically, graphitic ordering of free carbon along the free axis. That this peak can be fitted with a single Lorentzian peak is indicative of the presence of high-quality graphene in the sample. The size of this peak relative to the G-peak is also a good measure of the number of graphene layers present in the sample. That the I_{2D}/I_{G} ratio is 0.71 is suggestive of the presence of few layer graphene in the sample. The sheet resistance of the graphene composite is 0.25 Ohm-cm.

### Example 9. Materials Characterization of Graphene/Carbon Fiber Composite Derived from the Photothermal Pyrolysis of an Exemplary Precursor-Carbon Fiber and Polyaniline

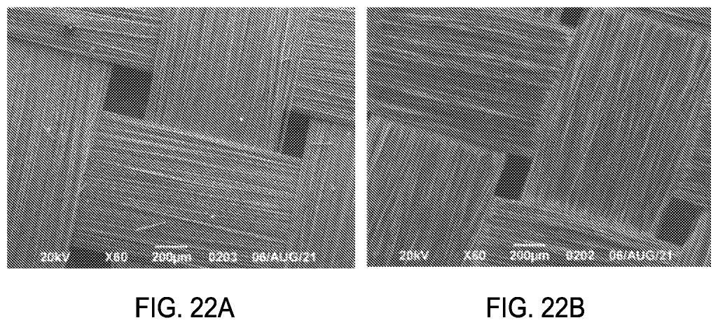

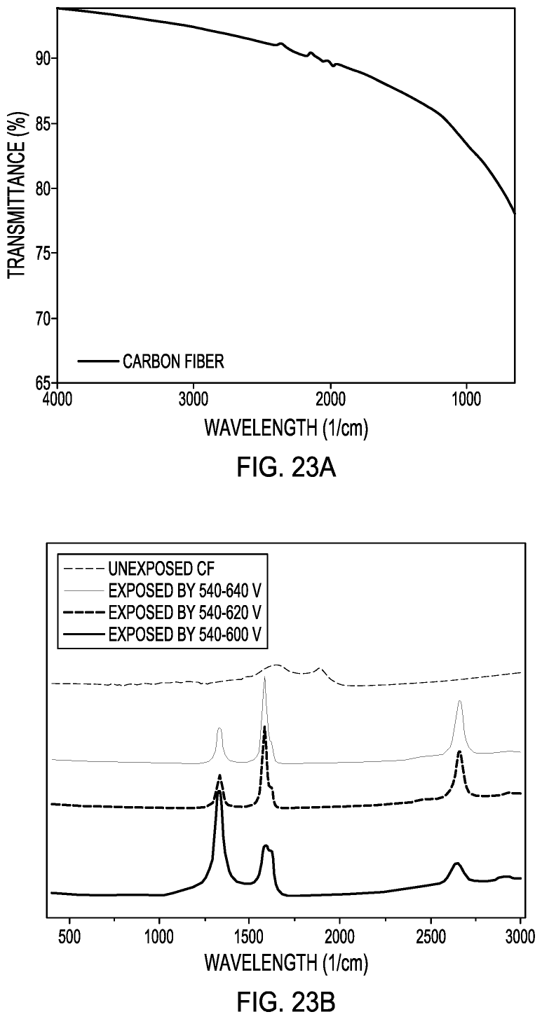

Pristine carbon fiber is made of graphite and has an absorption spectrum that overlaps well with the emission spectrum of the xenon flash lamp. It has a rather short radiation attenuation length. As such, irradiating it with high intensity flash lamp can thus exfoliate it into graphene layers. The surface morphology of the graphene/carbon fiber composite thus obtained was studied with scanning electron microscopy. FIGS. 22A-B show SEM images of pristine unpyrolyzed (A), and photothermally pyrolyzed (B) carbon fiber. FIG. 23A shows FTIR spectrum of pristine carbon fiber. The lack of structure in the spectrum of the pristine carbon fiber fabric confirmed that the precursor material was made of only pure carbon. Raman spectroscopy was used to investigate phase ordering and phase transformations of the carbon fiber upon photothermal pyrolysis.

FIG. 23B shows Raman spectra of pristine carbon fiber fabric and photothermally pyrolyzed pristine carbon fiber fabric as a function of xenon flash lamp pulse power. Photothermal process: (1) 540-640V: 20 pulses (0.5 Hz, 800 μs pulse length, and 540 V voltage) of areal energy density of 5.3 J/cm² per pulse, corresponding to total areal energy density of 106 J/cm²), followed by 20 pulses (1.0 Hz, 800 μs pulse length, and 640 V voltage) of areal energy density of 8.5 J/cm² per pulse, corresponding to total areal energy density of 170 J/cm²); (2) 540-620:20 pulses (0.5 Hz, 800 μs pulse length, and 540 V voltage) of areal energy density of 5.3 J/cm² per pulse, corresponding to total areal energy density of 106 J/cm²), followed by 20 pulses (1.0 Hz, 800 μs pulse length, and 620 V voltage) of areal energy density of 8.2 J/cm² per pulse, corresponding to total areal energy density of 164 J/cm²); (3) 20 pulses (0.5 Hz, 800 μs pulse length, and 540 V voltage) of areal energy density of 5.3 J/cm² per pulse, corresponding to total areal energy density of 106 J/cm²), followed by 20 pulses (1.0 Hz, 800 μs pulse length, and 600 V voltage) of areal energy density of 7.9 J/cm² per pulse, corresponding to total areal energy density of 158 J/cm²). The spectra confirm the formation of high-quality graphene from the photothermal pyrolysis of pristine carbon fiber, given the presence of the characteristic graphitic bands near 1582 cm⁻¹ (Graphitic, G-band) and 1350 cm⁻¹ (Disorder, D-band), as well as the 2D band near 2650 cm⁻. That the I_{D}/I_{G} ratio in the photothermally-pyrolyzed samples is less than 1.0 is indicative of high structural order in the graphene samples. The I_{D}/I_{G} ratio for the sample photothermally-pyrolyzed with the 540-620V process is 2.02. This process involved irradiating the sample with 20 pulses (at 0.5 Hz repetition rate, 800 μs pulse length, and 540 V voltage) of areal energy density of 5.3 J/cm² per pulse, corresponding to total areal energy density of 106 J/cm²), followed by 20 pulses (1.0 Hz, 800 μs pulse length, and 620 V voltage) of areal energy density of 8.2 J/cm² per pulse, corresponding to total areal energy density of 164 J/cm²). Further, that the 2D peak in the photothermally pyrolyzed samples can be fitted with a single Lorentzian peak is indicative of the presence of high-quality graphene in these samples. The size of this peak relative to the G-peak is also a good measure of the number of graphene layers present in the sample. That the ratio of the 2D-peak to the G-peak is 0.62 is indicative of the presence of few layer graphene in these photothermally-pyrolyzed samples. In contrast, the pristine, unpyrolyzed sample lacks 2D peak; it has rather broad and ill-defined D-peak and G-peak, suggesting the absence of graphene and a lack of structural order in the sample. The sheet resistance for the sample photothermally-pyrolyzed with the 540-620V is 0.02 Ohm-cm, indicating that this composite has good conductivity.

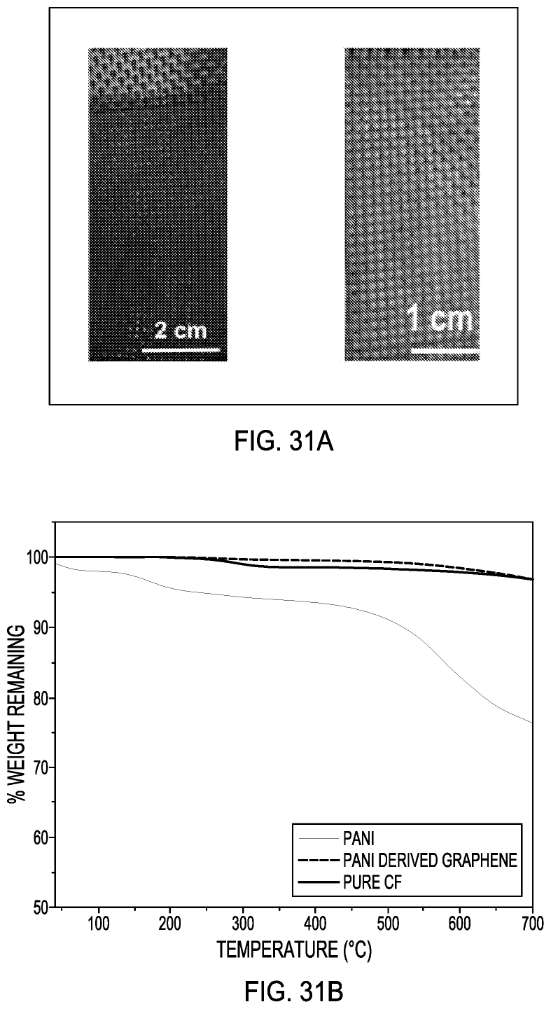

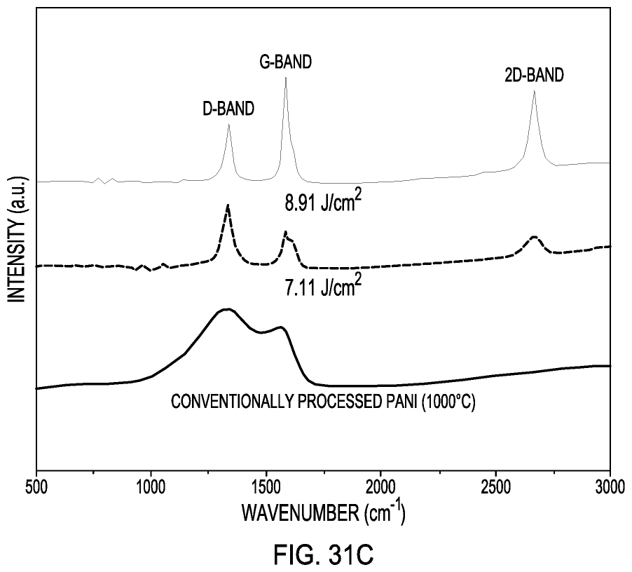

Polyaniline has an absorbance spectrum in the region of 500 nm-700 nm matching well with the emission spectrum of Xenon flash lamp. This enabled the photothermal conversion of PANI to graphene. FIG. 31A shows the optical image of PANI and derived graphene. A green color of the precursor film was an indicative of emeraldine form of PANI and a grey color of the photothermally processed firm was representative of transformation of PANI to carbonaceous materials. Conversion of PANI to carbon was confirmed by TGA as no mass loss is observed as shown in FIG. 31B.

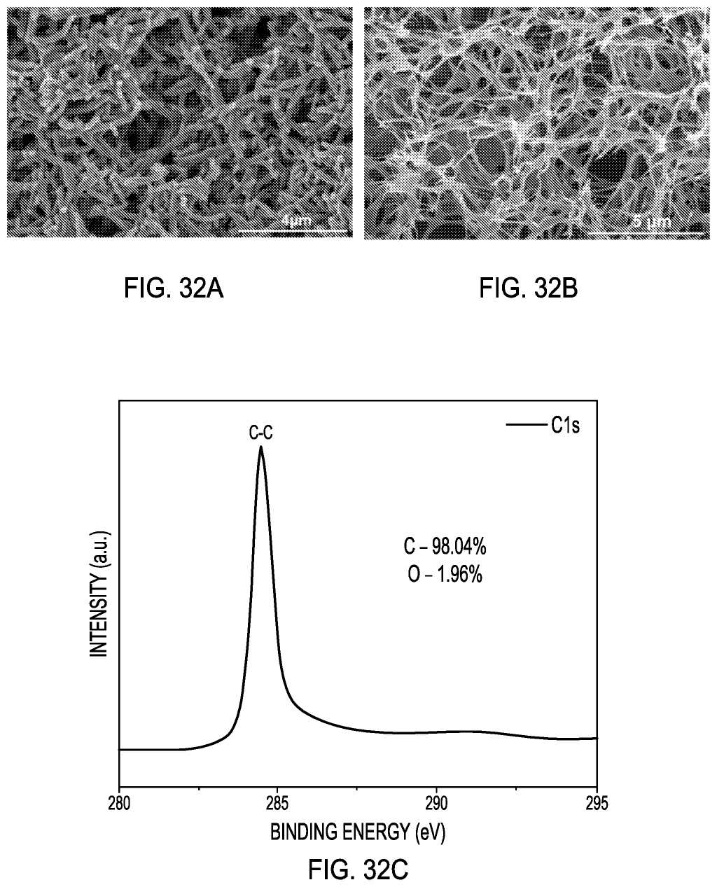

Raman spectroscopy was used to investigate the quality of carbon. The presence of D band, G band and 2D band as shown in FIG. 31C is a representative of graphitic structure as described earlier. Ratio of D band to G band of about 0.35 at 8.91 J/cm² input energy marks the presence of graphite with less defect in its structure. 2D band indicate the ordering of graphite along the free axis. For PANI derived graphene the presence of 2D band along with the ratio of 2D band to G band less than 1, indicating the formation of few layer graphene like that of polybenzoxazine derived graphene. Interestingly, conventionally carbonized PANI at 1000° C. exhibit diffused D and G band a representative of amorphous carbon. Hence, it can be asserted that the temperature accessed during the millisecond photothermal processing is higher than 1000° C. which resulted in the formation of high-quality graphene. Morphological investigation of the derived graphene was performed using SEM. Electrochemically deposited PANI exhibited rod like morphology as shown in FIG. 32A. The photothermal processing of PANI resulted in the formation of porous network of graphene (FIG. 32B). This macroporous morphology is very beneficial for the transport of electrolyte allowing the access of bulk material. Additionally, the fibrous structure of the graphene will enhance the electrode and electrolyte interaction, and this results in superior electrochemical performance. XPS was performed to determine the chemical composition of PANI derived graphene. Asymmetric peak centered at 284.5 eV as shown in FIG. 32C confirms the presence of sp² hybridized graphitic carbon which agrees well with the Raman data findings. Furthermore, carbon and oxygen atomic ratios is estimated to be 98% and 2% respectively, suggesting that the graphene is mostly composed of carbon even though the processing is done in air.

### Example 10. Applications in Electrochemical Energy Storage

Electrochemical energy application of graphene/carbon fiber composites derived via photothermal pyrolysis of polybenzoxazine exemplary precursor material was demonstrated on samples of the former that were coated with MnO₂. The high abundance, low cost, high electrochemical performance, and environmental inertness of MnO₂ make it an attractive candidate for supercapacitor electrode. Unfortunately, its low conductivity results in poor cyclability and low-rate capability of electrochemical energy storage devices prepared with it. Combining MnO₂ with carbonaceous materials like graphene is a viable strategy for overcoming the above-mentioned limitations of the former. But production of high-quality graphene in a scalable manner is fraught with a lot of challenges. Various aspects of the present invention can overcome these challenges and produce high-quality graphene at ambient conditions in milliseconds, and in a scalable manner.

The processing scheme for depositing MnO₂ pm graphene composites involves first subjecting graphene composites formed on carbon fiber substrates to UV-ozone treatment for 5 minutes on both sides to oxidize the surface, and thus increase its hydrophilicity. Next, MnO₂ is deposited on the graphene composite, using a three-electrode set up, where graphene on carbon fiber is used as working electrode, a Pt wire and Ag/AgCl are used as counter and reference electrodes, respectively. Immersing the three electrodes in an electrolyte containing aqueous solution of 50 mM manganese acetate II and 100 mM sodium sulfate and performing cyclic voltametric measurements in the potential range of 0-1.4V at the scan rate of 50 mV/s, leads to the deposition of MnO₂ on the graphene composite. The number of deposition cycles is varied between 5 cycles to 15 cycles to study the influence of amount of MnO₂ on the electrochemical performance. Following the MnO₂ deposition, the electrode surface is thoroughly washed using DI water, followed by drying at 100° C. in vacuum oven for 2 hr. The mass of deposited MnO₂ is calculated using a weighing balance with an accuracy of 0.01 mg.

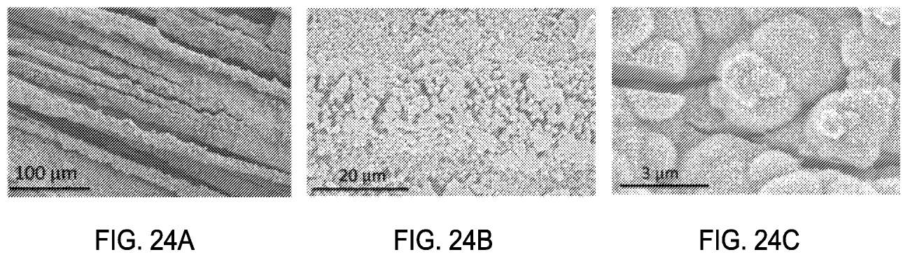

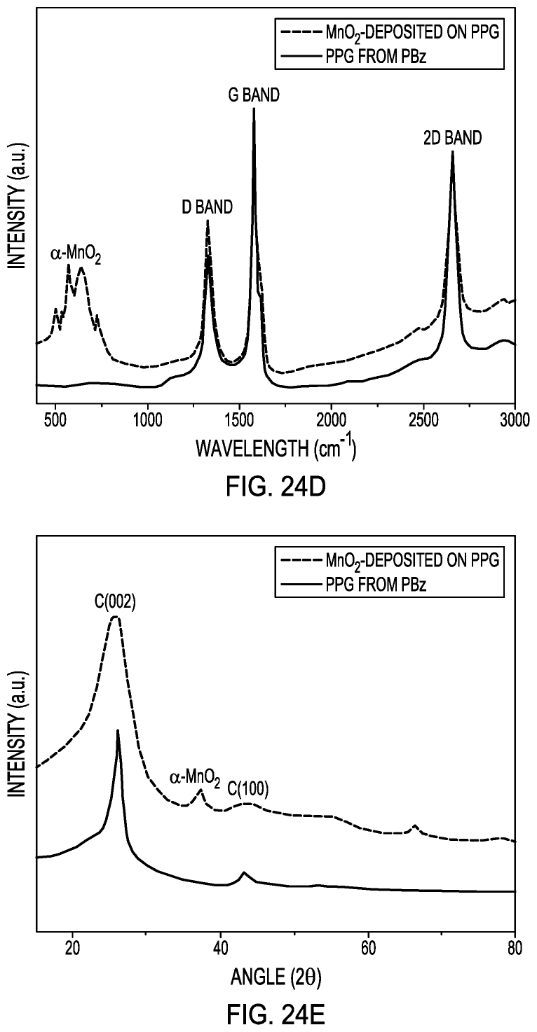

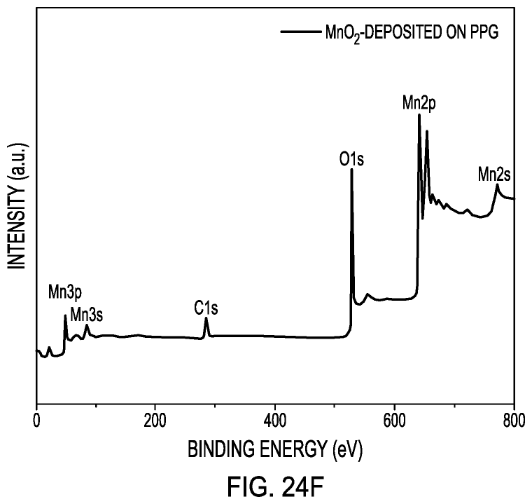

FIGS. 24A, B, and C show the SEM images of MnO₂ deposited on graphene composites at various magnifications. FIG. 24A confirms the conformal deposition of MnO₂ on graphene composite and FIG. 24C depicts the flower like architecture of the deposited MnO₂. This flower like architecture enhances the electrolyte and MnO₂ interaction due to its high surface area. In addition, macropores in the composites provide facile pathway for the transport of electrolyte to the bulk of the material, thus making these MnO₂/graphene composite a promising candidate for electrochemical energy storage applications. The deposited MnO₂ structure was further investigated using Raman, XRD and XPS as shown in FIGS. 24D-F. Raman spectra shown in FIG. 24D shows additional two peaks at 570 and 650 cm⁻¹ along with graphene peaks, are characteristic peak of Mn—O lattice. The peak at 36.9° in XRD confirmed the formation of partially crystallized alpha MnO₂ resulting from the electrochemical deposition. Elemental analysis performed using XPS is shown in FIG. 24F and indicates the presence of Mn (Mn₂ₚ, Mn₂ₛ, Mn₃ₛ), O₁ₛ and C₁ₛ, confirming the successful deposition of MnO₂.

Electrochemical characterization and electrochemical performance testing of the graphene composite derived from photothermal pyrolysis of polybenzoxazine exemplary precursor were all carried out using CHI660E electrochemical workstation (CH instruments Austin, TX) at ambient conditions. A three electrodes system was used to perform cyclic voltammetry, charge discharge test and electrochemical impedance spectroscopy, where photothermally produced graphene composite that was coated with MnO₂ was used as the working electrode, Pt wire was used as a counter electrode, and Ag/AgCl was used as the reference electrode. These measurements were conducted in electrolyte containing an aqueous solution of 0.5M Na₂SO₄. The performance of symmetric device using MnO₂ deposited graphene in both electrodes, with a separator made of cellulose filter paper that was pre-soaked in 0.5M Na₂SO₄, was also investigated.

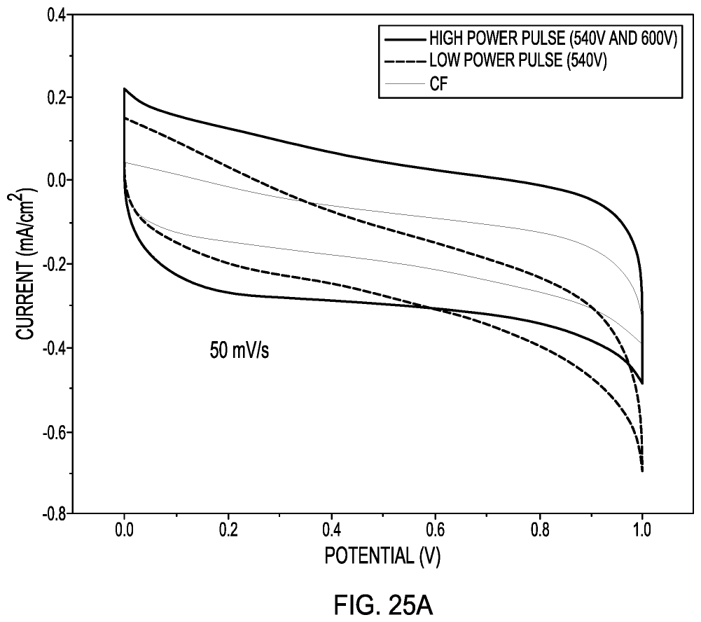

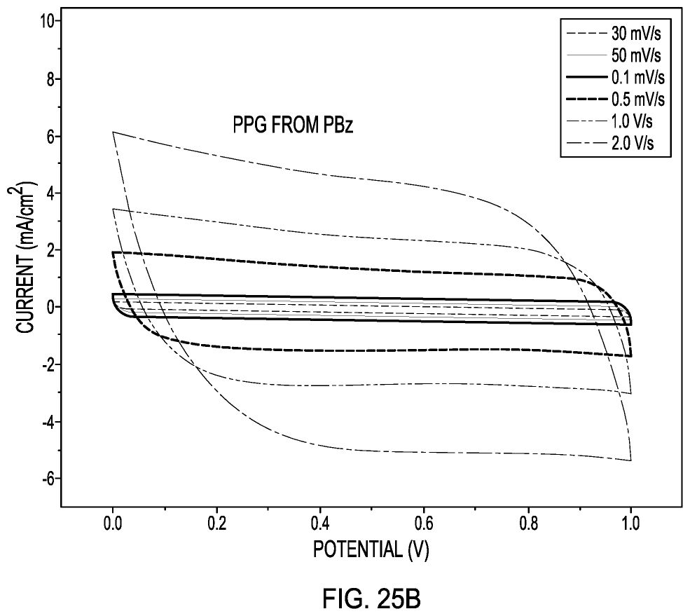

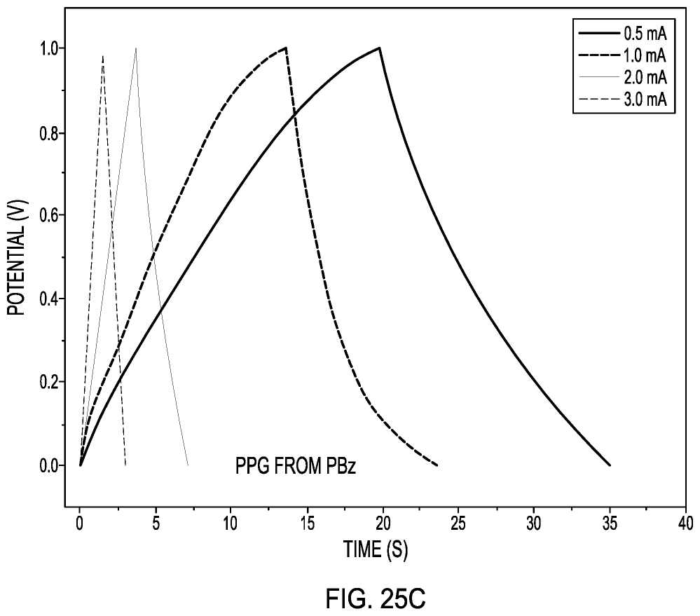

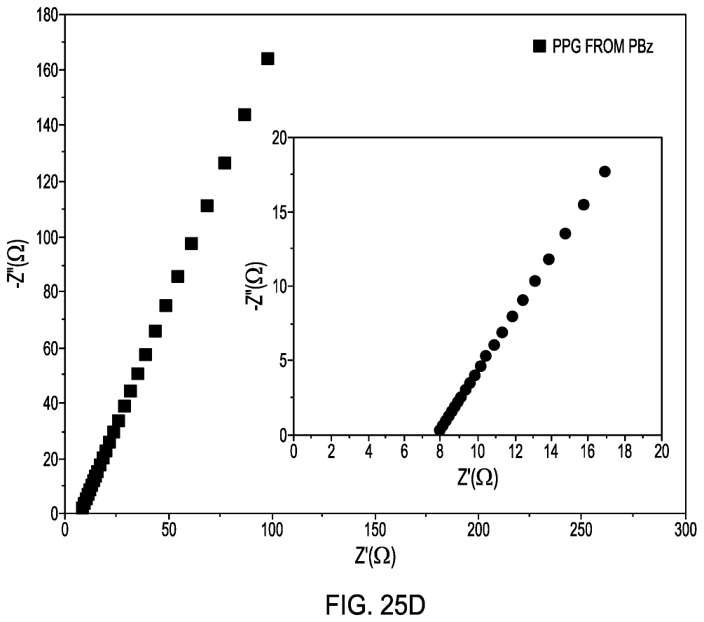

The high porosity, high electrical conductivity of graphene, along with the lack of binders in the graphene composites make the latter an ideal supercapacitor electrode. Photothermally produced graphene on carbon fiber fabric that was coated with MnO₂ was therefore evaluated as a supercapacitor electrode, using cyclic voltammetry (CV), and galvanostatic charge-discharge (GCD) was investigated. CV was conducted in the potential range of 0-1.0V using 0.5M aqueous Na₂SO₄. Photothermally-derived graphene from polybenzoxazine exemplary precursor as well as bare graphitic carbon fiber exhibited pseudo-rectangular CV curve at 50 mV/s (FIGS. 25A-D), indicating the EDLC behavior. The capacitance obtained from area under the CV curve is 3.6 mF/cm² and 1.5 mF/cm², respectively, of high-power pulse and low-power pulse produced graphene. The superior performance of high-power pulse processed sample relative to the low power one can be attributed to the higher porosity, higher degree of graphitization, along with superior conductivity, all of which promoted the adsorption of ions on its surface and facilitated charge transport. As such, all the other electrochemical analysis was conducted on graphene prepared using high power pulse. CV was performed at various scan rate to determine the charge transfer capabilities of graphene. It retained pseudo-rectangular shape till 2V/s, depicting the excellent charge propagation through the bulk of the material. This is further validated using GCD, where the sample maintained an isosceles triangle charge discharge profile, even at very high current density. Also, the capacitance value decreased by only 9%, even after 8-fold increment in the current density, and thus demonstrating the good rate capability of graphene-based supercapacitor. The obtained areal capacitance of 3.6 mF/cm² is among the highest reported value for graphene based micro-supercapacitor. Taken together, these results indicate the potential utility of photothermally-produced graphene on carbon fiber fabric EDLC type micro-supercapacitor applications.

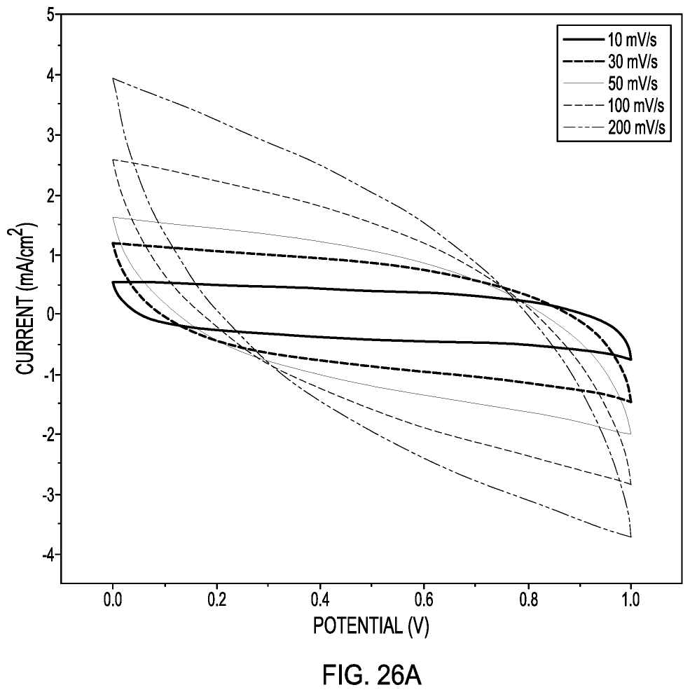

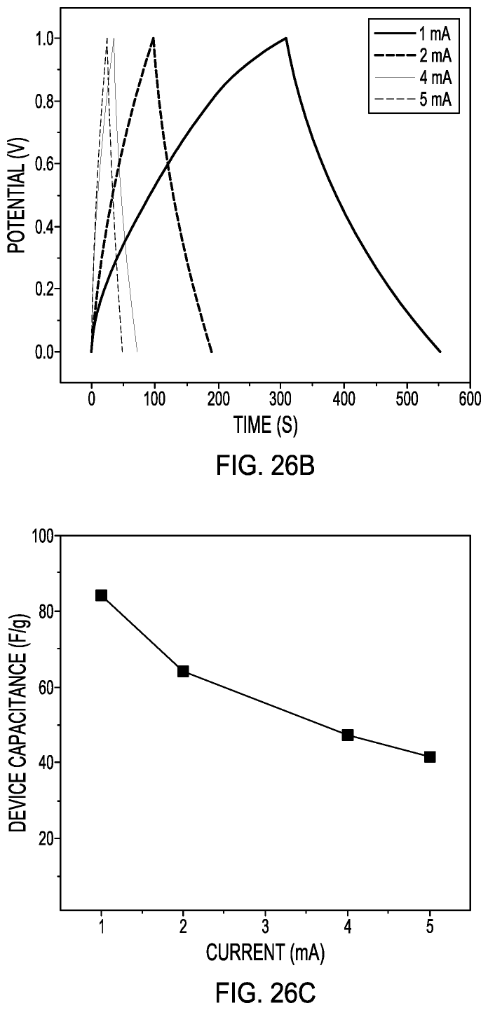

FIGS. 26A-C shows electrochemical performance test results obtained at various scan rate of symmetric device prepared using MnO₂ deposited on graphene composite derived from the photothermal pyrolysis of polybenzoxazine exemplary precursor (FIG. 26A), as well as GCD profile of the device at different current density (FIG. 26B), and capacitance (F/g) a function of current density (FIG. 26C).

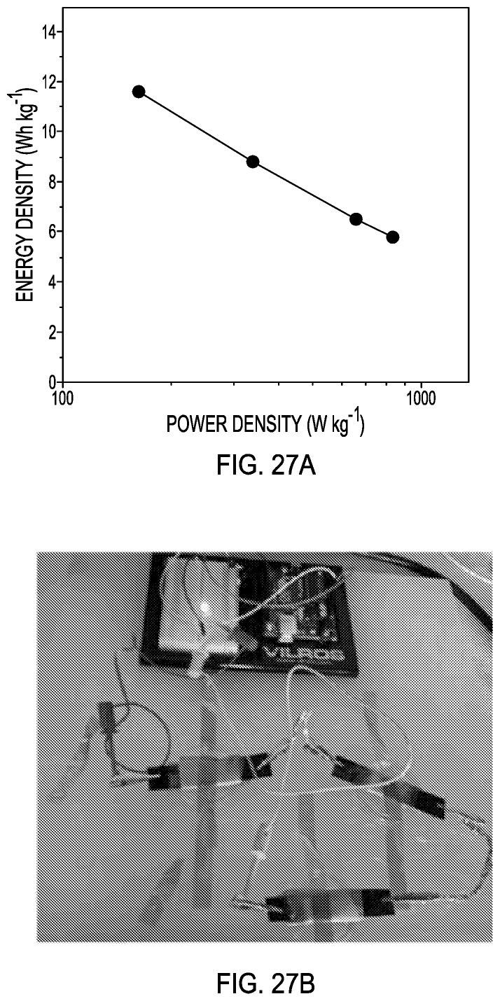

FIG. 27A shows a Ragone plot of symmetric device prepared using MnO₂ deposited on graphene composite derived from the photothermal pyrolysis of polybenzoxazine exemplary precursor. FIG. 27B shows the demonstration of three supercapacitor devices connected in series and lighting up an LED. The supercapacitors were fabricated with electrodes prepared using MnO₂ deposited on graphene composites derived from the photothermal pyrolysis of polybenzoxazine exemplary precursor

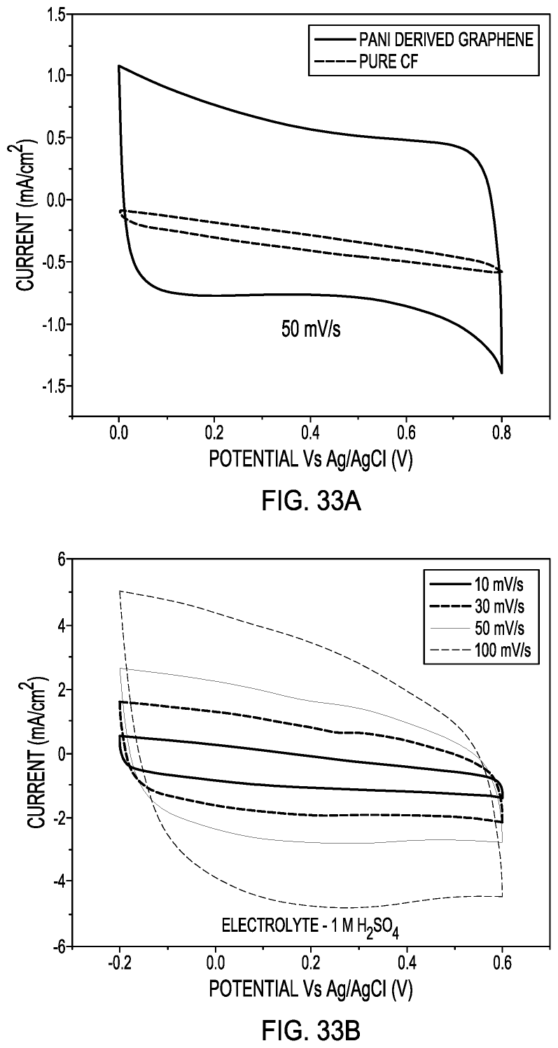

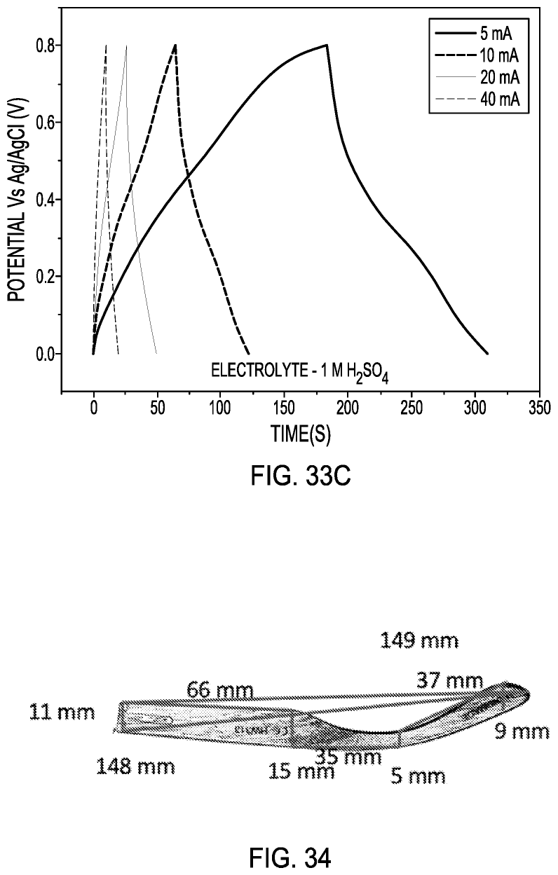

Electrochemical performance of photothermally derived graphene from PANI was determined considering its macroporous, high conductivity and fiber like architecture. A three electrode system was used to perform cyclic voltammetry (CV) and galvanostatic charge discharge (GCD) test like the one adopted for exemplary polybenzoxazine derived graphene. Graphene from PANI on CF was used as working electrode, Pt as counter electrode and Ag/AgCl as a reference electrode. Electrochemical measurements were conducted in aqueous salt solution of 0.5M Na₂SO₄ (sodium sulfate) and in 1M H₂SO₄ (sulfuric acid) electrolyte. CV of both CF and PANI derived graphene on CF was conducted in the potential range of 0-0.8 V at 50 mV/s. Both exhibited pseudo rectangular shape which is an indicative of ideal EDLC type behavior (FIG. 33A). Capacitance obtained from area under the curve is 22.4 mF/cm² and 1.5 mF/cm² respectively, of PANI derived graphene and CF. Capacitance of PANI derived graphene outperformed that of polybenzoxazine derived graphene. The superior performance of PANI derived graphene is mainly due to high porosity, fibrous structure and superior electrical conductivity which promote the adsorption as well as transport of ions across the bulk of the material. Interestingly, capacitance of PANI derived graphene increased to 100 mF/cm² at 10 mV/s when the capacitance was evaluated in acidic electrolyte (1M H₂SO₄) (FIG. 33B). The huge increment of capacitance in acidic electrolyte may have resulted from pseudocapacitive effect of oxygen functional group present in the graphene. GCD was also performed in the potential range of 0-0.8V at various current densities as shown in FIG. 33C to substantiate the findings from cyclic voltammetry. Sample maintained isosceles triangle shape even at very high current density of 40 mA. A capacitance of 185 mF/cm² was obtained on this sample at 5 mA, which is one of the highest capacitance values reported for graphene-based supercapacitor. Moreover, this device retained more than 60% of its capacitance at current density 40 mA which suggests good interfacial contact between graphene and CF, superior conductivity, and facile access of the bulk of the material. These findings indicate the control over morphology can significantly improve the device performance as demonstrated; this is an area which has not been explored before.

An illustrative exemplary application of the photothermally produced graphene from polyaniline on carbon fiber is an eyewear sidearm that stores electrochemical energy and which can be used for laser projection applications. The very high energy storage capacity and mechanical stability enabled by carbon fiber/graphene composite imbues the bespoke application considerable advantages. FIG. 34 shows the schematic image of the frame of eye wear side arm with proposed dimensions. Fabrication of the device entails producing large area graphene film on area as large as 15 cm by 15 cm, laser cutting graphene film to appropriate, and assembling the films in series or parallel configuration, with a solid-state electrolyte between the positive and negative electrode plate of each cell, to realize desired energy output.

### Example 11. Applications in Electromagnetic Interference Shielding

Graphene/carbon fiber composites derived from the photothermal pyrolysis of an exemplary precursor material—polybenzoxazine—were evaluated for electromagnetic interference (EMI) shielding applications.

Electro-magnetic parametric characterization and EMI shielding performance testing of graphene composites derived from the photothermal pyrolysis of exemplary precursor—polybenzoxazine.

EMI shielding effectiveness measurements of graphene/carbon fiber composites were conducted in accordance with ASTM D4935-99 μsing a vector network analyzer (VNA) series E5061B, Agilent Technologies. Samples were cut to fit the required shape and dimension of the analyzer sample holder. Thickness measurements were conducted using a digital micrometer.

The sample density was calculated from experimental measurements of the volume and mass. The material parameters (permittivity, conductivity, and permeability) of the composites were extracted from the EMI shielding measurement results of the composite over the three frequency bands investigated, namely, the C-, X-band and Ku-bands covering the frequency range of 5 GHz to 18 GHz.

Measurement of the electro-magnetic properties of the composites involved a four-step process. Following the loading of the sample into the sample holder, the experimental setup, including the VNA and the waveguide was calibrated, followed by the measurement of the scattering parameters of the sample. Next, the experimentally measured scattering parameters were modeled and simulated. By fitting the model to measured S-parameters, permittivity (ε), permeability (μ), and conductivity (σ) of the composite were readily extracted.

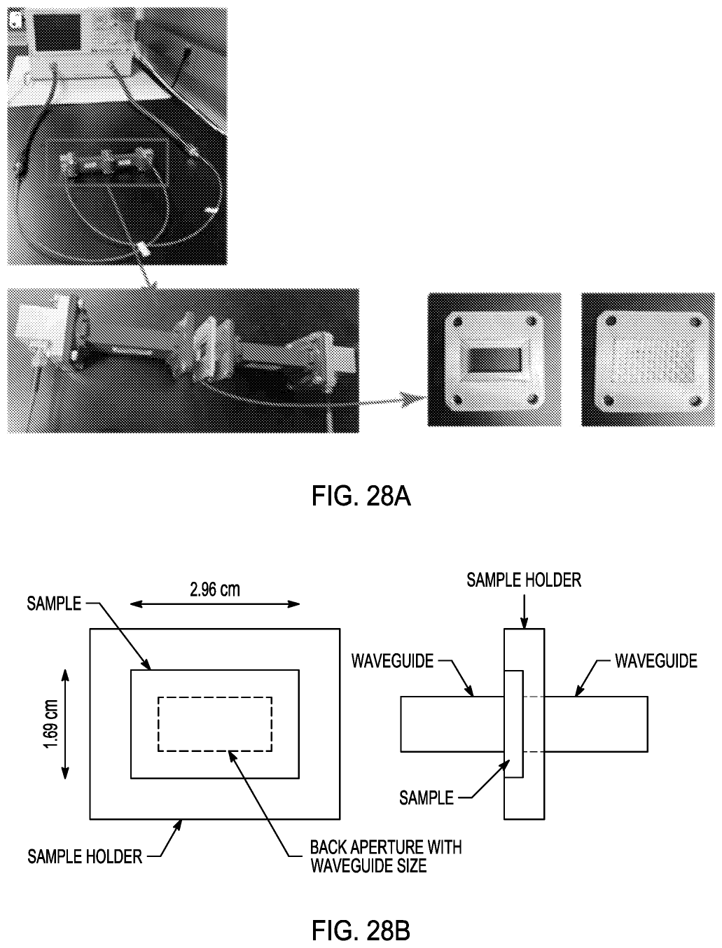

FIG. 28A illustrates a photograph of an experimental setup for EMI shielding measurement, including a programmable network analyzer, waveguide, and sample holder assembly (top left), a photograph showing a close-up of the sample holder assembly, in accordance with various aspects (bottom left), a photograph showing a close of the sample holder (middle) and a photograph showing the sample within the sample holder (right), in accordance with various aspects. The setup includes a programmable VNA (vector network analyzer) series E5061B, Agilent Technologies, and its cables, and three different set of waveguides (WR137, WR90, and WR62), which have working frequency ranges of 5 to 8 GHz, 8 to 12 GHz, and 12 to 18 GHz. Each of these setups were calibrated and used in accordance with the Transmission-Reflection-Length (TRL) approach. A sample holder was constructed to enable EMI shielding measurement for each working frequency band. These sample holders were designed to minimize the sensitivity of the measurement to variations in the size of the samples. FIG. 28B illustrates a schematic showing a front view of the sample placed within the sample holder (left), and a schematic showing a side view of sample placement within the sample holder (right). The setup could measure EMI shielding effectiveness of up to 120 dB.

A sample of the composite material was inserted in the middle of a rectangular waveguide and the complex reflection and transmission coefficients of the waveguide with and without the sample were measured using the VNA. The measurement results of the waveguide without the sample were used as a calibration for eliminating the effect of the coaxial to rectangular waveguide adapters. The reflection and transmission for the waveguide with the sample were simulated and the effective material parameters (permittivity (ε), permeability (μ), and conductivity (σ)) of the composite were extracted by fitting the simulation results to the measurement results and by using the material parameters as the fitting parameters. For the samples with potentially anisotropic parameters, the measurements and the simulations were performed for two different polarizations of the incident wave (i.e., the TE and TM modes of the waveguide). The shielding properties (i.e., shielding effectiveness, absorption, and reflection) for different thicknesses of the composite materials were then computed from the extracted material parameters. The composite material model was refined using the measured material parameters and potential approaches for increasing the shielding effectiveness were identified.

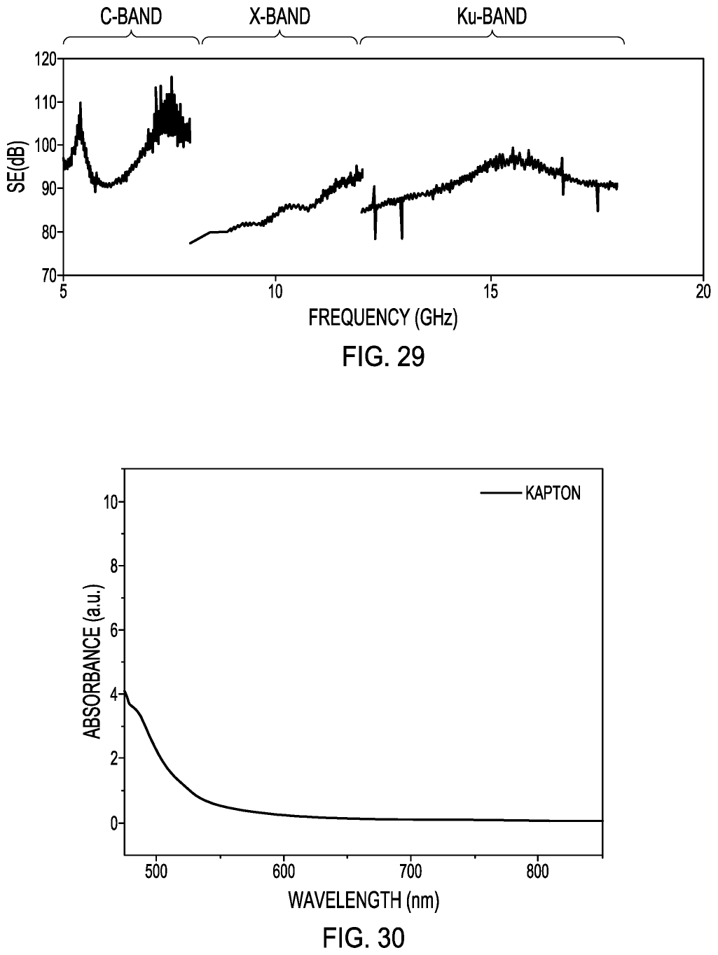

FIG. 29 shows EMI shielding performance of graphene/carbon fiber composite in 2-layer configuration of 400 μm thick. This result indicates that graphene/carbon fiber composites yielded EMI shielding effectiveness of greater than 80 dB over the multi-band C-, X, and Ku-bands frequencies. Recognizing that decibels are logarithmic, the 80 dB EMI shielding effectiveness indicates that greater than 99.99999% of the incident radiation is attenuated with this composite

### Example 12. Applications of Various Aspects of the Present Invention in Printed and Flexible Electronics

Graphene derived from the photothermal pyrolysis of a screen-printed exemplary precursor material—cPAN and poly (BZ)—coated on flexible polyimide films was evaluated for printed and flexible electronics applications.

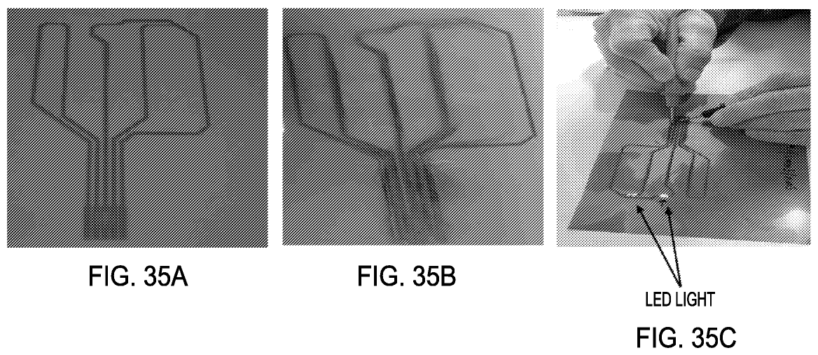

Shown in FIGS. 35A-C is a demonstration of graphene LED circuit used in lighting up a white light LED device. FIG. 35A shows the screen-printed trace of cPAN, an exemplary precursor, on flexible polyimide substrate. FIG. 35B shows graphene trace of LED circuit, realized from the photothermal pyrolysis of the screen-printed cPAN precursor of FIG. 35A. FIG. 35C shows the successfully integration of white light LED devices onto the graphene trace, as well as the demonstration of actual lighting of the LED devices, driven by an external power supply.

### Example 13. Physical Properties and Device Performance Indicators

Summarized in Table 1 are physical properties and device performance indicators of the graphene composites of various aspects of the present invention. Relative to their counterparts processed with conventional methods, the graphene composites of various aspects of the present invention are of much higher quality as indicated by their I_{D}/I_{G} ratio (<1.0); they have much better properties in terms of their morphology as indicated by their enormous porosity; they have lower sheet resistance (0.15 Ohm-cm for carbon fiber/graphene composites). In contrast, graphene composites made by laser carbonization have reported sheet resistance that is 21-33 Ohm-cm, about 140-220 times larger than that of various aspects of the present invention. The polyimide/graphene composite of various aspects of the present invention has good electrical conductivity (150 S/m). The composites of various aspects of the present invention also have improved performance relative to the composites derived via conventional pyrolysis, as indicated by their multi-band C-, X- and Ku-bands EMI shielding performance of greater than 80 dB, by their high areal capacitance (3 mF/cm²) when used as micro-supercapacitors electrodes.

TABLE 1
Physical properties of the graphene composites of various aspects of the present invention.

| Composite | Carbon fiber/graphene | | Si/graphene | | Carbon fiber/graphene |
|---|---|---|---|---|---|
| Photothermal process | 20 pulses (0.5 Hz, 800 μs | | 70 pulses (1.0 Hz, 500 μs | | 20 pulses (0.5 Hz, 500 |
| | pulse length, and 540 V | | pulse length, and 540 V | | μs pulse length, and 540 |
| | voltage) or areal energy | | voltage) of areal energy | | V voltage) of areal |
| | density of 5.3 J/cm² + 20 | | density of 3 J/cm² | | energy density of 5.3 |
| | pulses (1.0 Hz, 800 μs | | | | J/cm² |
| | pulse length, and 620 V | | | | |
| | voltage) of areal energy | | | | |
| | density of 8.2 J/cm² | | | | |
| Precursor film | Polybenzoxazine | | Polybenzoxazine | | Polybenzoxazine |
| | (unpatterned) | | (imprint lithographically- | | (unpatterned) |
| | | | patterned) | | |
| Property | | | | | |
| Thickness | | | 10 | μm | |
| Raman spectra I_{D}/I_{G} | 0.46 | | 0.4 | | 1.29 |
| Raman spectra I_{2D}/I_{G} | 0.65 | | 0.64 | | 0.57 |
| Sheet resistance | 0.15 | Ohm-cm | 0.25 | Ohm-cm | |

| EMI shielding | C-band: 100 dB | | | | |
|---|---|---|---|---|---|
| effectiveness (2-layer | X-band: 85 dB | | | | |
| configuration, 400 μm | Ku-band: 95 dB | | | | |
| thick | | | | | |
| Areal capacitance | 3.6 | mF/cm² | | | 2.2 mF/cm² |
| Composite | Polyimide/graphene | | Polyimide/graphene | | Carbon fiber/graphene |
| Photothermal process | 20 pulses (1.0 Hz, 500 μs | | 20 pulses (1.0 Hz, 500 μs | | 20 pulses (0.5 Hz, 800 |
| | pulse length, and 490 V | | pulse length, and 490 V | | μs pulse length, and 540 |
| | voltage) of areal energy | | voltage) of areal energy | | V voltage) of areal |
| | density of 2.5 J/cm² | | density of 2.5 J/cm². | | energy density of 5.3 |
| | | | | | J/cm² + 20 pulses (1.0 |
| | | | | | Hz, 800 μs pulse length, |
| | | | | | and 620 V voltage) of |
| | | | | | areal energy density of |
| | | | | | 8.2 J/cm² |
| Precursor firm | Cyclized | | Cyclized | | Carbon fiber |
| | polyacrylonitrile (screen | | polyacrylonitrile | | |
| | printed) | | | | |
| Property | | | | | |
| Thickness | 2 | μm | 50 | μm | 146 μm (total |
| | | | | | thickness) |

| Raman spectra I_{D}/I_{G} | 0.63 | | 2.02 |
|---|---|---|---|
| Raman spectra I_{2D}/I_{G} | 0.71 | | 0.62 |
| Sheet resistance | 0.21 | Ohm-cm | 0.02 Ohm-cm |

| | | |
|---|---|---|
| Conductivity | 150 | S/m |

| | |
|---|---|
| Permittivity | 100 |

Many graphene preparation methods have been reported in the literature. These methods can be broadly categorized into top-down or bottom-up approaches. In top-down approaches, graphene is prepared via mechanical exfoliation, chemical exfoliation of graphite and graphite oxide, laser exfoliation of graphite, chemical reduction of graphene oxide, electrochemical reduction of graphene oxide, photothermal reduction of GO and photolysis of various precursors using flash lamp, and direct CO₂ laser carbonization of polymeric precursors with absorption spectra that has significant overlap with the emission wavelength of the laser between the short range of 9.4 μm and 10.6 μm, which occurs exclusively within the mid-IR band. In bottom-up approaches, graphene is produced via solution-based chemical synthesis, via solvothermal synthesis, via chemical vapor deposition on different substrates such as metallic catalysts (copper, ruthenium, nickel), via epitaxial growth on SiC, via laser-induced epitaxial growth, as well as via arc discharge.

Although flash lamps have been used in the past to prepare graphene, the precursors used in these preparatory methods are different from the precursors of various aspects of the present invention. Further, the quality of the graphene as indicated by the low I_{D}/I_{G} (see Table 1) obtained with the methods presented in various aspects of the present invention is far superior to those reported in the literature cited above. Still further, distinct differences exist in the ways in which the radiation field is modulated and applied in various aspects of the present invention relative to those reported in the literature.

Of all the above indicated methods for making graphene, direct CO₂ laser carbonization, based on laser flash photothermal pyrolysis, is most closely related to xenon flash lamp photothermal pyrolysis of various aspects of the present invention. Photonic processing using xenon flash lamp sources with emission spectrum that spans 200 nm-1000 nm wavelength range offers several advantages over CO₂ lasers, namely, reduced cost and complexity, improved efficiency in converting electrical energy to light, scalability to large area processing, broadband illumination that overlaps the near-UV, visible, and near-IR regions of the electromagnetic spectrum, which encompasses a much broader selection set of potential precursor materials with moieties that under flash photons pulse illumination are able to undergo photothermal and photochemical transformations, mediated by valence electronic transitions, molecular vibrations, phonon/lattice vibrations, and molecular rotations. The energy of a single photon within 300 and 400 nm wavelength of the emission band of the xenon flash lamp, corresponding to 4.1 eV-3.1 eV, is sufficient to directly break some of the bonds in the precursor polymer. The combination of photo-induced bond breaking with the induction of lattice vibrations in the precursor polymer ultimately leads to efficient photothermal pyrolysis, carbonization, and graphitization.

In contrast, the emission of CO₂ laser used in carbonization of polymeric precursors has an emission spectrum with wavelengths within a rather short band between 9.4 μm and 10.6 μm that occurs exclusively within the mid-IR band. This limits the pool of suitable materials to materials that are only active in the mid-IR range, and thus can only undergo photothermal transformations, mediated by molecular vibration and phonon/lattice vibration. The energy of a single photon within 9.4 μm and 10.6 μm wavelength of the emission band CO₂ laser, corresponding to 0.12 eV-0.13 eV, is insufficient to directly break any bond in the precursor polymer. Therefore, the CO₂ laser radiation induces phonons in the precursor polymer, leading to bond dissociation, photothermal pyrolysis, carbonization, and graphitization.

A good illustration of the above fine distinction between the photothermal and photochemical basis of xenon flash lamp photothermal pyrolysis and laser photothermal pyrolysis is illustrated in the absorption spectrum of Kapton™, a polyimide substrate used commonly in printed electronics and flexible circuit boards because of its outstanding properties: high oxidative stability, high mechanical strength, high modulus, excellent electrical and optical properties, and superior chemical resistance. Kapton™ shows a broad UV absorption band in the UV region between 180 and 400 nm (FIG. 30), which allows for the effective absorption of all common excimer and exciplex laser wavelengths, including 193, 248, 308, and 351 nm, and hence its use in ablation studies and applications. Polyimide is not the only organic polymer with this type of absorption characteristics. In fact, organic polymers absorb ultraviolet radiation strongly, making excimer laser ablation of these materials to occur efficiently.

It is generally believed that the mechanism of its laser ablation is mainly photothermal, with a little bit of photochemical features. While Kapton™ undergoes excimer laser-induced ablation above the laser fluence threshold of 40 mJ/cm² in the near-UV region that does not form graphene, it is rather carbonized to graphene upon irradiation with high intensity continuous wave or pulsed CO₂ laser in the frequency band of 9.4 μm and 10.6 μm in the mid-IR region. However, under irradiation of a precursor such as cyclized polyacrylonitrile with high intensity xenon flash lamp, whereby the absorption spectrum of the precursor has peaks that overlap with the emission spectrum of the xenon flash lamp in the near-UV region, the precursor is photothermally pyrolyzed to graphene, with no effect whatsoever on the Kapton, as shown in FIGS. 21A-B.

It is equally important to note that while the screen-printed features of the precursor film of FIGS. 21A-B is converted to high-quality, few layer graphenes, as indicated by the I_{D}/I_{G} ratio of 0.63 and I_{2D}/I_{G} ratio of 0.71, respectively, the open areas of the Kapton™ substrate that were not coated with the precursor film were neither ablated, nor photothermally pyrolyzed to graphene during the process. Herein then lies a distinction between the high intensity pulsed xenon flash lamp photothermal pyrolysis process of various aspects of the present invention and the high intensity CO₂ laser photothermal process on the one hand, as well as between the high intensity pulsed xenon flash lamp photothermal process of various aspects of the present invention and the excimer laser photothermal process, on the other hand. In other words, the xenon flash lamp photothermal pyrolysis can convert suitable precursors to high quality graphene within the mid-UV band, while the excimer lasers can only ablate the precursor films without converting them to graphene. Further, while the CO₂ laser photothermal process can carbonize Kapton™ to graphene within the short wavelength band between 9.4 μm and 10.6 μm, it cannot do so outside of this short band of the electromagnetic spectrum, which limits its applicability to only a handful of precursor materials with reasonable absorption in the mid-IR region of the spectrum. The xenon flash lamp photothermal process, utilizing a broad wavelength source that spans the near-UV, visible, and even near-IR regions of the spectrum can carbonize a much wider selection of absorptive precursors within the above indicated bands to graphene than CO₂ laser-based photothermal process. Another shortcoming of CO₂ laser-based photothermal process is that the IR emission wavelengths prohibits its use in high resolution application.

It should also be emphasized that coating of appropriate precursors followed by photothermal graphitization of that precursor is an additive process, by which the substrate itself is not damaged and by which the precursor and substrate can be independently selected. Independent selection of the precursor provides advantages in tuning the properties of the graphene material on any arbitrary substrate. By contrast the CO₂ laser graphitization of polymer films is subtractive, etches/damages the substrates, and because the substrate itself is converted to graphene does not allow for the independent selection of substrate and precursor.

The terms and expressions that have been employed are used as terms of description and not of limitation, and there is no intention in the use of such terms and expressions of excluding any equivalents of the features shown and described or portions thereof, but it is recognized that various modifications are possible within the scope of the aspects of the present invention. Thus, it should be understood that although the present invention has been specifically disclosed by specific aspects and optional features, modification and variation of the concepts herein disclosed may be resorted to by those of ordinary skill in the art, and that such modifications and variations are considered to be within the scope of aspects of the present invention.

### Exemplary Aspects

The following exemplary aspects are provided, the numbering of which is not to be construed as designating levels of importance:

Aspect 1 provides a method for the formation of a graphene film, the method comprising:
coating a polymeric graphene precursor on a substrate; and
irradiating the polymeric graphene precursor coated on the substrate with a pulsed high intensity light source emitting at more than a single wavelength and with a pulse duration of less than one second, to convert the polymeric graphene precursor to the graphene film.

Aspect 2 provides the method of Aspect 1, wherein the graphene film is a graphene composite film.

Aspect 3 provides the method of any one of Aspects 1-2, wherein the graphene film is a graphene non-composite film.

Aspect 4 provides the method of any one of Aspects 1-3, wherein the polymeric precursor and the substrate have different chemical compositions.

Aspect 5 provides the method of any one of Aspects 1-4, wherein the irradiating comprises irradiating the polymeric graphene precursor and the substrate.

Aspect 6 provides the method of any one of Aspects 1-5, wherein the irradiating of the polymeric graphene precursor and the substrate does not convert the substrate to a material comprising graphene.

Aspect 7 provides the method of any one of Aspects 1-6, wherein the light source comprises emission wavelengths that are in the range of 100 nm to 2000 nm.

Aspect 8 provides the method of any one of Aspects 1-7, wherein the light source comprises emission wavelengths that are in the range of 300 nm to 800 nm.

Aspect 9 provides the method of any one of Aspects 1-8, wherein the light source comprises emission wavelengths that are in the range of 400 nm to 600 nm.

Aspect 10 provides the method of any one of Aspects 1-9, wherein the pulse duration is shorter than a thermal equilibrium time of the polymeric graphene precursor.

Aspect 11 provides the method of any one of Aspects 1-10, wherein the pulse duration is 1 to 999 milliseconds.

Aspect 12 provides the method of any one of Aspects 1-11, wherein the pulse duration is 200 to 900 milliseconds.

Aspect 13 provides the method of any one of Aspects 1-12, wherein the pulse duration is 400 to 800 milliseconds.

Aspect 14 provides the method of any one of Aspects 1-13, wherein the light source has an intensity of 100 V to 2000 V.

Aspect 15 provides the method of any one of Aspects 1-14, wherein the light source has an intensity of 400 V to 700 V.

Aspect 16 provides the method of any one of Aspects 1-15, wherein the light source has a pulse frequency of 0.001 Hz to 1000 Hz.

Aspect 17 provides the method of any one of Aspects 1-16, wherein the light source has a pulse frequency of 0.1 Hz to 10 Hz.

Aspect 18 provides the method of any one of Aspects 1-17, wherein the light source has a pulse frequency of 0.5 Hz to 1 Hz.

Aspect 19 provides the method of any one of Aspects 1-18, wherein the light source has an energy density per pulse of 0.1 J/cm² to 100 J/cm².

Aspect 20 provides the method of any one of Aspects 1-19, wherein the light source has an energy density per pulse of 1 J/cm² to 10 J/cm².

Aspect 21 provides the method of any one of Aspects 1-20, wherein the light source has an energy density per pulse of 2 J/cm² to 9 J/cm².

Aspect 22 provides the method of any one of Aspects 1-21, wherein the light source has a total areal density of 30 J/cm² to 200 J/cm².

Aspect 23 provides the method of any one of Aspects 1-22, wherein the irradiating comprises 5 to 1000 pulses of the light source.

Aspect 24 provides the method of any one of Aspects 1-23, wherein the irradiating comprises 10 to 40 pulses of the light source.

Aspect 25 provides the method of any one of Aspects 1-24, wherein the irradiating pyrolyzes the polymeric graphene precursor.

Aspect 26 provides the method of any one of Aspects 1-25, wherein coating the polymeric graphene precursor on the substrate comprises printing, offset printing, ink jet printing, transfer printing, aerosol jet printing, microcontact printing, embossing, nanoimprint lithography, optical lithography lithography, electron beam lithography, ion beam lithography, or a combination thereof.

Aspect 27 provides the method of any one of Aspects 1-26, wherein the polymeric graphene precursor on the substrate comprises a patterned polymeric graphene precursor.

Aspect 28 provides the method of Aspect 27, wherein the method comprises coating the polymeric graphene precursor on the substrate and subsequently patterning the polymeric graphene precursor coating to form the patterned polymeric graphene precursor coated on the substrate.

Aspect 29 provides the method of any one of Aspects 27-28, wherein the method comprises coating the patterned polymeric graphene precursor coating on the substrate.

Aspect 30 provides the method of any one of Aspects 27-29, wherein coating the polymeric graphene precursor on the substrate comprises printing, offset printing, ink jet printing, transfer printing, aerosol jet printing, microcontact printing, or a combination thereof, to form the patterned polymeric graphene precursor coated on the substrate.

Aspect 31 provides the method of any one of Aspects 27-30, wherein coating the polymeric graphene film on the substrate comprises embossing, nanoimprint lithography, or a combination thereof, to form the patterned polymeric graphene precursor coated on the substrate.

Aspect 32 provides the method of any one of Aspects 27-31, wherein coating the polymeric graphene film on the substrate comprises optical lithography lithography, or electron beam lithography, or ion beam lithography, to form the patterned polymeric graphene precursor coated on the substrate.

Aspect 33 provides the method of any one of Aspects 1-32, wherein the polymeric graphene precursor comprises a polymer that comprises a disubstituted benzene, a benzene substituted with one or more chromophores, polycyclic aromatic rings, or a combination thereof.

Aspect 34 provides the method of any one of Aspects 1-33, wherein the polymeric graphene precursor comprises a polymer that comprises nitroaniline, aniline, nitrophenol, biphenyl, nitrobenzene, benzaldehyde, acetophenone, pyrene, pentacene, anthracene, tetracene, or a combination thereof.

Aspect 35 provides the method of any one of Aspects 1-34, wherein the polymeric graphene precursor comprises a polymer chosen from resol, an oligomer of pyrene pitch, cyclized polyacrylonitrile, carbon fiber, polyaniline, a thermosetting resin network formed from blending and crosslinking polybenzoxazines with an epoxy, and combinations thereof.

Aspect 36 provides the method of any one of Aspects 1-35, wherein the polymeric graphene precursor comprises a polymer chosen from poly(3-phenyl-2,4-dihydro-1,3-benzoxazine), poly(phenyl benzoxazine), poly(3-furanyl-2,4-dihydro-1,3-benzoxazine), poly(furanyl benzoxazine), poly(phenol-co-formaldehyde), resol, oligomers of pyrene pitch, cyclized polyacrylonitrile, pristine carbon fiber, polyaniline, a thermosetting resin network formed from blending and crosslinking polybenzoxazines with bis-phenol-A furfuryl diglycidyl ether, and combinations thereof.

Aspect 37 provides the method of any one of Aspects 1-36, wherein an absorption band of the polymeric graphene precursor overlaps with an emission band of the pulsed light source.

Aspect 38 provides the method of any one of Aspects 1-37, wherein the polymeric graphene precursor has an absorption band in the range of 100 nm to 2000 nm.

Aspect 39 provides the method of any one of Aspects 1-38, wherein the polymeric graphene precursor has an absorption band in the range of 300 nm to 800 nm.

Aspect 40 provides the method of any one of Aspects 1-39, wherein the polymeric graphene precursor has an absorption band in the range of 400 nm to 600 nm.

Aspect 41 provides the method of any one of Aspects 1-40, wherein the substrate comprises plastic, metal, fabric, textile fabric, or a combination thereof.

Aspect 42 provides the method of any one of Aspects 1-41, wherein the substrate comprises carbon.

Aspect 43 provides the method of Aspect 42, wherein the substrate comprises a carbon fiber.

Aspect 44 provides the method of any one of Aspects 42-43, wherein the substrate comprises a carbon mesh.

Aspect 45 provides the method of any one of Aspects 42-44, wherein the substrate comprises a carbon fabric.

Aspect 46 provides the method of any one of Aspects 42-45, wherein the substrate comprises a carbon composite.

Aspect 47 provides the method of any one of Aspects 42-46, wherein the substrate comprises a graphene composite.

Aspect 48 provides the method of any one of Aspects 42-47, wherein the substrate comprises graphene.

Aspect 49 provides the method of any one of Aspects 42-48, wherein the substrate comprises a carbon film.

Aspect 50 provides the method of any one of Aspects 1-49, wherein the light source comprises a xenon flash lamp.

Aspect 51 provides the method of any one of Aspects 1-50, wherein the light source comprises a halogen flashlamp.

Aspect 52 provides the method of any one of Aspects 1-51, wherein the light source comprises a light emitting diode.

Aspect 53 provides the method of any one of Aspects 1-52, wherein the light source comprises one or more light emitting diodes.

Aspect 54 provides the method of any one of Aspects 1-53, wherein the irradiating comprises irradiating the polymeric graphene precursor coated on the substrate in air.

Aspect 55 provides the method of any one of Aspects 1-54, wherein the irradiating comprises irradiating the polymeric graphene precursor at a temperature that is less than 100° C.

Aspect 56 provides the method of any one of Aspects 1-55, wherein the irradiating comprises maintaining the polymeric graphene precursor at a temperature that is less than 100° C.

Aspect 57 provides the method of any one of Aspects 1-56, wherein the irradiating comprises irradiating the polymeric graphene precursor at room temperature.

Aspect 58 provides the method of any one of Aspects 1-57, wherein the irradiating comprises substantially maintaining a pre-irradiation temperature of the polymeric graphene precursor throughout the irradiating.

Aspect 59 provides the method of any one of Aspects 1-58, wherein the irradiating comprises increasing a temperature of the polymeric graphene precursor by less than or equal to 10° C.

Aspect 60 provides the method of any one of Aspects 1-59, wherein the irradiating comprises increasing a temperature of the polymeric graphene precursor by less than or equal to 2° C.

Aspect 61 provides the method of any one of Aspects 1-60, wherein the graphene film has a conductivity of at least 150 S/m.

Aspect 62 provides the method of any one of Aspects 1-61, wherein the graphene film has a ratio of less than 1.0 between a characteristic disorder band (D-band) with a peak near 1350 cm⁻¹ and a characteristic graphitic band (G band) with a peak near 1582 cm⁻¹, as determined by Raman spectroscopy.

Aspect 63 provides the method of any one of Aspects 1-62, wherein the graphene film has a ratio of less than 1 between a characteristic 2Dband with a peak near 2700 cm⁻¹ and a characteristic graphitic band (G band) with a peak near 1582 cm⁻¹ that is fittable with a single Lorentzian function, as determined by Raman spectroscopy.

Aspect 64 provides the method of any one of Aspects 1-63, wherein the irradiating comprises localizing light absorption to the precursor film such that a temperature of the polymeric graphene precursor increases by less than or equal to 10° C. during the irradiating relative to a pre-irradiation temperature of the precursor film.

Aspect 65 provides the method of any one of Aspects 1-64, wherein the method leaves the substrate free of damage relative to a state of the substrate prior to the coating and irradiating.

Aspect 66 provides the method of any one of Aspects 1-65, wherein the irradiating comprises pulse power modulation.

Aspect 67 provides the method of Aspect 66, comprising tuning a microstructure of the graphene film using the pulse power modulation.

Aspect 68 provides a graphene film formed by the method of any one of

### Aspects 1-67.

Aspect 69 provides a patterned graphene film produced by the method of any one of Aspects 1-67.

Aspect 70 provides an electrochemical energy storage device, an electromagnetic shielding material, a chemical or biological sensor, a post-CMOS nanoelectronic device, a heat shielding material, a structural composite, a filter, or a combination thereof, comprising a graphene film formed by the method of any one of Aspects 1-67.

Aspect 71 provides a method for the formation of a graphene film, the method comprising:
coating a polymeric graphene precursor on a substrate that comprises a carbon fiber, carbon mesh, carbon fabric, carbon composite, graphene composite, graphene, a carbon film, or a combination thereof, wherein the polymeric graphene precursor and the substrate have different chemical compositions; and
irradiating the polymeric precursor coated on the substrate with a pulsed high intensity light source emitting at more than a single wavelength and with a pulse duration of less than one second, to convert the polymeric graphene precursor to the graphene film.

Aspect 71 provides the method, graphene film, electrochemical energy storage device, electromagnetic shielding material, chemical or biological sensor, post-CMOS nanoelectronic device, heat shielding material, structural composite, filter, or any combination of aspects 1-70 optionally configured such that all elements or options recited are available to use or select from.

What is claimed is:

1. A method for the formation of a graphene film, the method comprising:
coating a polymeric graphene precursor on a substrate; and
irradiating the polymeric graphene precursor coated on the substrate with a pulsed high intensity light source emitting at more than a single wavelength and with a pulse duration of less than one second, to convert the polymeric graphene precursor to the graphene film.

2. The method of claim 1, wherein a composition of the polymeric graphene precursor is different than a composition of the substrate.

3. The method of claim 1, wherein the light source comprises emission wavelengths that are in the range of 100 nm to 2000 nm.

4. The method of claim 1, wherein the pulse duration is 200 to 900 milliseconds, the light source has an intensity of 100 V to 2000 V, the light source has a pulse frequency of 0.1 Hz to 10 Hz, the light source has an energy density per pulse of 0.1 J/cm² to 100 J/cm², and the light source has a total areal density of 10 J/cm² to 1000 J/cm².

5. The method of claim 1, wherein coating the polymeric graphene precursor on the substrate comprises printing, offset printing, ink jet printing, transfer printing, aerosol jet printing, microcontact printing, embossing, nanoimprint lithography, optical lithography lithography, electron beam lithography, ion beam lithography, or a combination thereof.

6. The method of claim 1, wherein the polymeric graphene precursor on the substrate comprises a patterned polymeric graphene precursor.

7. The method of claim 1, wherein the polymeric graphene precursor comprises a polymer that comprises a disubstituted benzene, a benzene substituted with one or more chromophores, polycyclic aromatic rings, aniline, nitroaniline, nitrophenol, biphenyl, nitrobenzene, benzaldehyde, acetophenone, pyrene, pentacene, anthracene, tetracene, or a combination thereof.

8. The method of claim 1, wherein the polymeric graphene precursor comprises a polymer chosen from resol, an oligomer of pyrene pitch, cyclized polyacrylonitrile, carbon fiber, polyaniline, a thermosetting resin network formed from blending and crosslinking polybenzoxazines with an epoxy, poly(3-phenyl-2,4-dihydro-1,3-benzoxazine), poly(phenyl benzoxazine), poly(3-furanyl-2,4-dihydro-1,3-benzoxazine), poly(furanyl benzoxazine), poly(phenol-co-formaldehyde), resol, oligomers of pyrene pitch, a thermosetting resin network formed from blending and crosslinking polybenzoxazines with bis-phenol-A furfuryl diglycidyl ether, and combinations thereof.

9. The method of claim 1, wherein an absorption band of the polymeric graphene precursor overlaps with an emission band of the pulsed light source, wherein the polymeric graphene precursor has an absorption band in the range of 400 nm to 600 nm.

10. The method of claim 1, wherein the substrate comprises plastic, metal, fabric, textile fabric, or a combination thereof.

11. The method of claim 1, wherein the substrate comprises a carbon fiber, carbon mesh, carbon fabric, carbon composite, graphene composite, graphene, a carbon film, or a combination thereof.

12. The method of claim 1, wherein the light source comprises a xenon flash lamp.

13. The method of claim 1, wherein the irradiating comprises irradiating the polymeric graphene precursor coated on the substrate in air and at room temperature.

14. The method of claim 1, wherein the irradiating comprises irradiating and/or maintaining the polymeric graphene precursor at a temperature that is less than 100° C.

15. The method of claim 1, wherein the polymeric graphene precursor comprises polyaniline.

16. The method of claim 1, wherein the graphene film has a conductivity of at least 150 S/m.

17. The method of claim 1, wherein the graphene film has:
a ratio of less than 1.0 between a characteristic disorder band (D-band) with a peak near 1350 cm⁻¹ and a characteristic graphitic band (G band) with a peak near 1582 cm⁻¹, as determined by Raman spectroscopy,
a ratio of less than 1 between a characteristic 2Dband with a peak near 2700 cm⁻¹ and a characteristic graphitic band (G band) with a peak near 1582 cm⁻¹ that is fittable with a single Lorentzian function, as determined by Raman spectroscopy, or
a combination thereof.

18. A method for the formation of a graphene film, the method comprising:
coating a polymeric graphene precursor on a substrate that comprises a carbon fiber, carbon mesh, carbon fabric, carbon composite, graphene composite, graphene, a carbon film, or a combination thereof, wherein the polymeric graphene precursor and the substrate have different chemical compositions; and
irradiating the polymeric precursor coated on the substrate with a pulsed high intensity light source emitting at more than a single wavelength and with a pulse duration of less than one second, to convert the polymeric graphene precursor to the graphene film.

19. A graphene film formed by the method of claim 1.

20. An electrochemical energy storage device, an electromagnetic shielding material, a chemical or biological sensor, a post-CMOS nanoelectronic device, a heat shielding material, a structural composite, a filter, or a combination thereof, comprising a graphene film formed by the method of claim 1.
